(19) United States
(12) Patent Application Publication
(10) Pub. No.: US 2025/0338727 A1
(43) Pub. Date: Oct. 30, 2025

(54) DISPLAY DEVICE

(71) Applicant: Samsung Display Co., Ltd., Yongin-si (KR)

(72) Inventors: Ju Hyun HWANG, Yongin-si (KR); Young Seo PARK, Yongin-si (KR); Jae Young LEE, Yongin-si (KR)

(21) Appl. No.: 18/984,860

(22) Filed: Dec. 17, 2024

(30) Foreign Application Priority Data
Apr. 25, 2024 (KR) 10-2024-0055376

(51) Int. Cl. H10K 59/123; H10K 59/13; H10K 59/40

(52) U.S. Cl. CPC H10K 59/123; H10K 59/13; H10K 59/40

(57) ABSTRACT

A display device including a transmission area disposed in a display area and transmitting light provided from an outside includes a substrate, a thin film transistor layer disposed on the substrate and including a plurality of thin film transistors, a light emitting element layer disposed on the thin film transistor layer, wherein the light emitting element layer may include a plurality of first pixel electrodes electrically connected to the thin film transistors, a light emitting structure disposed on the first pixel electrodes, a second pixel electrode disposed on the light emitting structure and including a transmission hole overlapping the transmission area, and an auxiliary layer disposed in the transmission hole, wherein the auxiliary layer may include a photoluminescent layer absorbing light of a specific wavelength and performing photoluminescence, and a weak adhesion layer disposed on the photoluminescent layer.

This application claims priority to Korean Patent Application No. 10-2024-0055376, filed on Apr. 25, 2024, and all the benefits accruing therefrom under 35 U.S.C. § 119, the content of which in its entirety is herein incorporated by reference.

### BACKGROUND

### 1. Technical Field

The invention relates to a display device, and more particularly, to a display device including a transmission area through which light incident from an outside may be transmitted.

### 2. Description of the Related Art

As society develops, the demand for information and a display device for displaying an image is increasing in various forms. For example, the display device may be applied to various electronic devices such as a smart phone, a digital camera, a notebook computer, a navigation device, and a smart television. The display device may be a flat panel display device such as a liquid crystal display device, a field emission display device, or an organic light emitting display device.

The display device may include a display panel having a plurality of pixels connected to scan lines, data lines, and power lines to display an image. In addition, the display device may include a proximity sensor for sensing whether a user is positioned near the front of the display device, an illuminance sensor for sensing an illuminance of a front surface of the display device, an iris sensor for recognizing an iris of the user, a camera device for shooting a still image and a video, and the like.

As a display device is applied to various electronic devices display devices having various designs are required. For example, in the case of a smart phone, a display device capable of widening the display area by removing holes formed on the front surface of the display device is required. In this case, the sensor devices that have been disposed in the holes formed on the front surface of the display device may be disposed to overlap the display panel.

### SUMMARY

In an embodiment, a display device capable of displaying in an area where a sensor and a camera are disposed is provided.

However, the is not limited to the above-described embodiment and may be expanded variously without departing from the spirit and scope of the invention.

According to an embodiment, a display device including a transmission area disposed in a display area outputting a display and transmitting light provided from an outside source may include a substrate, a thin film transistor layer disposed on the substrate and including a plurality of thin film transistors, a light emitting element layer disposed on the thin film transistor layer, wherein the light emitting element layer may include a plurality of first pixel electrodes electrically connected to the respective thin film transistors, a light emitting structure disposed on the first pixel electrodes, a second pixel electrode disposed on the light emitting structure and including a transmission hole extending to the transmission area and overlapping the transmission area in a plan view, and an auxiliary layer disposed in the transmission hole, where the auxiliary layer may include a photoluminescent layer absorbing light of a specific wavelength and performing photoluminescence, and a weak adhesion layer disposed on the photoluminescent layer.

In an embodiment, the photoluminescent layer may include an organic material absorbing long-wave UV light of about 315 nm to about 400 nm and emitting visible light.

In an embodiment, the weak adhesion layer may include a material having an interface adhesive strength to the second pixel electrode that is lower than a material of the photoluminescent layer.

In an embodiment, the auxiliary layer may further include a mixed layer disposed between the photoluminescent layer and the weak adhesion layer, where the mixed layer may include a material in which a photoluminescent material forming the photoluminescent layer and a weak adhesion material forming the weak adhesion layer are mixed.

In an embodiment, a containing ratio of the photoluminescent material contained in the mixed layer may be greater than a containing ratio of the weak adhesion material.

In an embodiment, a portion of the mixed layer disposed adjacent to the photoluminescent layer may contain more of the photoluminescent material than the weak adhesion material, and another portion of the mixed layer disposed adjacent to the weak adhesion layer may contain more of the weak adhesion material than the photoluminescent material.

In an embodiment, a containing ratio of the photoluminescent material contained in the mixed layer may decrease along a direction from the photoluminescent layer to the weak adhesion layer, and wherein a containing ratio of the weak adhesion material contained in the mixed layer may increase along the direction from the photoluminescent layer to the weak adhesion layer.

In an embodiment, a containing ratio of the photoluminescent material contained in the mixed layer may decrease linearly along a direction from the photoluminescent layer to the weak adhesion layer, and wherein a containing ratio of the weak adhesion material contained in the mixed layer may increase linearly along the direction from the photoluminescent layer to the weak adhesion layer.

In an embodiment, a containing ratio of the photoluminescent material contained in the mixed layer may decrease parabolically along a direction from the photoluminescent layer to the weak adhesion layer, and wherein a containing ratio of the weak adhesion material contained in the mixed layer may increase parabolically along the direction from the photoluminescent layer to the weak adhesion layer.

In an embodiment, the light emitting structure may include a light emitting layer generating light, a first functional layer disposed between the first pixel electrodes and the light emitting layer, and a second functional layer disposed between the second pixel electrode and the light emitting layer.

In an embodiment, the first functional layer may include an organic material and may extend to the transmission area so as to overlap the transmission hole in a plan view, the second functional layer may include an organic material and may extend to the transmission area so as to overlap the transmission hole in a plan view, wherein the second functional layer may be disposed on the first functional layer in the transmission area, and the photoluminescent layer may be disposed on the second functional layer in the transmission area.

In an embodiment, the thin film transistor layer may further include a plurality of insulating layers, wherein one insulating layer of the plurality of insulating layers may be disposed under the first pixel electrodes and may cover the other insulating layers of the plurality of insulating layers except for the one insulating layer, wherein the one insulating layer may extend to the transmission area so as to overlap the transmission hole, and wherein the auxiliary layer may be disposed on the one insulating layer in the transmission hole.

In an embodiment, the respective other insulating layers may include holes overlapping the transparent hole.

In an embodiment, a display device including a transmission area disposed in a display area outputting a display and transmitting light provided from an outside source may include a substrate, a thin film transistor layer disposed on the substrate and including a plurality of thin film transistors, and a light emitting element layer disposed on the thin film transistor layer, wherein the light emitting element layer may include a plurality of first pixel electrodes electrically connected to the thin film transistors, a light emitting structure disposed on the first pixel electrodes, a second pixel electrode disposed on the light emitting structure and including a transmission groove overlapping the transmission area and an auxiliary layer disposed under the second pixel electrode and overlapping the transmission groove, wherein the auxiliary layer may include a photoluminescent layer absorbing light of a specific wavelength and performing photoluminescence, and a weak adhesion layer disposed on the photoluminescent layer.

In an embodiment, a portion of the second pixel electrode overlapping the auxiliary layer may have a first thickness, and an other portion of the second pixel electrode that does not overlap the auxiliary layer may have a second thickness, wherein the first thickness may be thinner than the second thickness.

In an embodiment, the photoluminescent layer may include an organic material absorbing long-wave UV light of about 315 nm to about 400 nm and emitting visible light.

In an embodiment, the weak adhesion layer may include a material having an interface adhesive strength to the second pixel electrode that is lower than a material of the photoluminescent layer.

In an embodiment, the auxiliary layer may further include a photoluminescent material forming the photoluminescent layer, and a mixed layer formed of a material in which a weak adhesion material forming the weak adhesion layer is mixed, wherein the mixed layer may be disposed between the photoluminescent layer and the weak adhesion layer.

In an embodiment, the light emitting structure may include a light emitting layer generating light, a first functional layer disposed between the first pixel electrodes and the light emitting layer, a second functional layer disposed between the second pixel electrode and the light emitting layer, wherein the first functional layer may include an organic material and may extend to the transmission area so as to overlap the transmission groove in a plan view, the second functional layer may include an organic material and may extend to the transmission area to overlap the transmission groove in a plan view, and the photoluminescent layer may be disposed on the second functional layer in the transmission area.

In an embodiment, the thin film transistor layer may further include a plurality of insulating layers, wherein one insulating layer of the plurality of insulating layers may be disposed under the first pixel electrodes and may cover the other insulating layers of the plurality of insulating layers except for the one insulating layer, wherein the one insulating layer may extend to the transmission area so as to overlap the transmission groove, and wherein the photoluminescent layer may be disposed on the one insulating layer in the transmission area.

The invention is not limited to that described above, and solutions which are not described may be clearly understood by those skilled in the art from this specification and the attached drawings.

According to an embodiment, the display device yield may be improved and a transmittance of the transmittance area may be improved. For example, by disposing the photoluminescent layer, which absorbs light of a specific wavelength and emits light recognizable through an industrial microscope, and the weak adhesion layer, which has a low interface adhesive strength to a metal material, to overlap the transmission area, a deposition material may be accurately deposited at a targeted position by accurately aligning a position of a mask during a deposition process, and the transmittance of the transmission area may be improved because a pixel electrode is not formed in the transmission area.

However, an effect of the invention is not limited to the effect described above, and may be expanded variously without departing from the spirit and scope of the invention.

### BRIEF DESCRIPTION OF THE DRAWINGS

The above and other features of the invention will become more apparent by describing in further detail embodiments thereof with reference to the accompanying drawings, in which:

FIG. 1 is a perspective view of a display device, according to an embodiment;

FIG. 2 is an exploded perspective view of the display device shown in FIG. 1, according to an embodiment;

FIG. 3 is a plan view of a display module, according to an embodiment;

FIG. 4 is a plan view of a display module, according to another embodiment;

FIG. 5 is a side view of a display panel illustrating an aspect before a protrusion area of the display panel shown in FIG. 4 is bent, according to an embodiment;

FIG. 6 is a side view of the display panel illustrating an aspect in which the protrusion area of the display panel shown in FIG. 5 is bent, according to an embodiment;

FIG. 7 is a cross-sectional view taken along line I-I′ of the display module in FIG. 3, according to an embodiment;

FIG. 8 is a plan view of a display unit of the display panel shown in FIG. 7, according to an embodiment;

FIG. 9 is a plan view illustrating a touch sensing layer shown in FIG. 7, according to an embodiment;

FIG. 10 is an enlarged view of a portion EA1 of FIG. 9, according to an embodiment;

FIG. 11 is a cross-sectional view taken along line II-II′ of FIG. 10, according to an embodiment;

FIG. 12 is an enlarged plan view illustrating a first area and a second area shown in FIG. 4 in more detail, according to an embodiment;

FIG. 13 is a cross-sectional view taken along line III-III′ of FIG. 12, according to an embodiment;

FIG. 14 is a schematic cross-sectional view illustrating a stack structure of an auxiliary layer, according to an embodiment;

FIG. 15 is a schematic cross-sectional view illustrating a stack structure of an auxiliary layer, according to another embodiment;

FIG. 16 is a graph illustrating a comparison of a containing ratio of a photoluminescent material and a weak adhesion material based on a thickness of the auxiliary layer shown in FIG. 15, according to an embodiment;

FIG. 17 is a modified example of the graph shown in FIG. 16, according to an embodiment;

FIG. 18 is another modified example of the graph shown in FIG. 16, according to an embodiment;

FIG. 19 is further another modified example of the graph shown in FIG. 17, according to an embodiment;

FIG. 20 is a cross-sectional view illustrating a thin film transistor layer and a light emitting element layer shown in FIG. 13, according to an embodiment;

FIG. 21 illustrates a cross-sectional view of a second pixel electrode shown in FIG. 13, according to an embodiment; and

FIG. 22 illustrates a cross-sectional view of a second pixel electrode shown in FIG. 20, according to an embodiment.

### DETAILED DESCRIPTION

Hereinafter, embodiments of the invention is described in detail with reference to the accompanying drawings. It should be noted that in the following description, only portions necessary for understanding an operation of the invention are described, and descriptions of other portions are omitted in order not to obscure the subject matter of the disclosure. In addition, the invention may be embodied in other forms without being limited to the embodiment described herein. However, the embodiment described herein is provided to describe in detail enough information to easily implement the technical spirit of the invention to those skilled in the art to which the invention belongs.

Throughout the specification, in a case where a portion is “connected” to another portion, the case includes not only a case where the portion is “directly connected” but also a case where the portion is “indirectly connected” with another component interposed therebetween. Terms used herein are for describing a specific embodiment and are not intended to limit the invention. For example, singular expressions include plural expressions unless the context clearly dictates otherwise. In addition, in a case where a certain portion “includes”, the case means that the portion may further include another component without excluding another component unless otherwise stated. “At least any one of X, Y, and Z” and “at least one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Terms such as first and second may be used to describe various components, but are used to distinguish such a component from another component. Therefore, a first component may refer to a second component within a range without departing from the scope of the invention.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto. Various embodiments of the invention are described with reference to drawings schematically illustrating ideal embodiments. Accordingly, it will be expected that shapes may vary, for example, according to tolerances and/or manufacturing techniques. Therefore, the embodiments disclosed herein should not be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

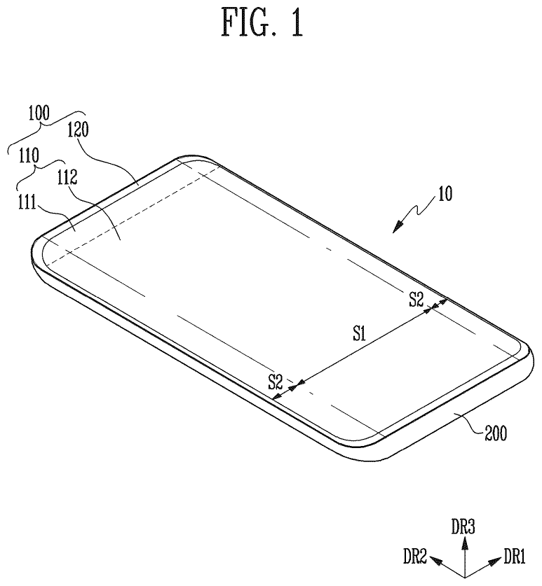

FIG. 1 is a perspective view illustrating a display device, according to an embodiment.

In an embodiment and referring to FIG. 1, the display device 10 refers to a device that may provide visual information, such as a moving image or a photo, to a user. The display device 10 may be used as a display screen of various products such as a television, a laptop, a monitor, a billboard, and Internet of things (IOT) as well as a mobile phone, a smart phone, a tablet personal computer (PC), a smart watch, a watch phone, a mobile communication terminal, an electronic notebook, an e-book, a portable multimedia player (PMP), a navigation, and an ultra mobile PC (UMPC). In addition, the display device 10 may also be used as a center information display (CID) disposed on an instrument panel, a center fascia, or a dashboard of a car, a room mirror display replacing a side mirror, and a display installed in a rear surface of a front seat as an entertainment device for a back seat. However, in the present specification, for convenience of description, an embodiment where the display device 10 is used as a smartphone is illustrated.

In an embodiment, the display device 10 may include a first surface S1 which is flat and second surfaces S2 extending from a left side and a right side of the first surface S1. Both of the second surfaces S2 may be flat or may be a curved surface. In another embodiment, one second surface S2 may be flat and the other second surface S2 may be a curved surface. When one of the second surfaces S2 is flat, an angle formed by the corresponding second surface S2 and the first surface S1 may be an obtuse angle. Meanwhile, when one of the second surfaces S2 is a curved surface, the second surface S2 may have a constant curved surface or a changing curvature.

In an embodiment and referring to FIG. 1, the second surfaces S2 are shown to extend from the left and right sides of the first surface S1 to the left and right sides, respectively, but are not limited thereto. That is, in an embodiment, one second surface S2 may extend only from one of the left side or the right side of the first surface S1. In addition, at least one second surface S2 may extend from at least one of an upper side and a lower side as well as the left side and the right side of the first surface S1. Hereinafter, the invention is described based on a structure in which the second surfaces S2 are disposed at an edge of a left side and a right side of the display device 10, as shown in FIG. 1.

In an embodiment, the display device 10 may include a cover window 100 and a lower cover 200.

In an embodiment, the cover window 100 may be positioned on the first surface S1 and the second surface S2 and may include a transmission cover portion 110 and a light blocking cover portion 120.

The transmission cover portion 110 may be disposed on at least a portion of the first surface S1 and at least a portion of the second surface S2 and may include a first sub-transmission cover portion 111 and a second sub-transmission cover portion 112.

The first sub-transmission cover portion 111 may correspond to a partial area of the transmission cover portion 110 and may be positioned near one side edge of the transmission cover portion 110 (that is, an upper edge based on a second direction DR2), but is not limited thereto. For example, the first sub-transmission cover portion 111 may be disposed near a lower edge of the transmission cover portion 110 based on the second direction DR2 or it may be disposed at left and right edges of the transmission cover portion 110. In another embodiment, the first sub-transmission cover portion 111 may be defined at an arbitrary position other than an edge of the transmission cover portion 110 according to where other components to be described later are disposed. Meanwhile, the second sub-transmission cover portion 112 may be all of the remaining areas of the transmission cover portion 110 except for the first sub-transmission cover portion 111.

In an embodiment, the light blocking cover portion 120 may include an opaque material. According to an embodiment, the light blocking cover portion 120 may be provided as a deck layer including a pattern that may be recognized to the user.

In an embodiment, the lower cover 200 may be positioned under the cover window 100 and may be combined with the cover window 100 to provide an internal empty space that receives various components to be described later. The lower cover 200 may include at least one of plastic or metal, but is not limited thereto.

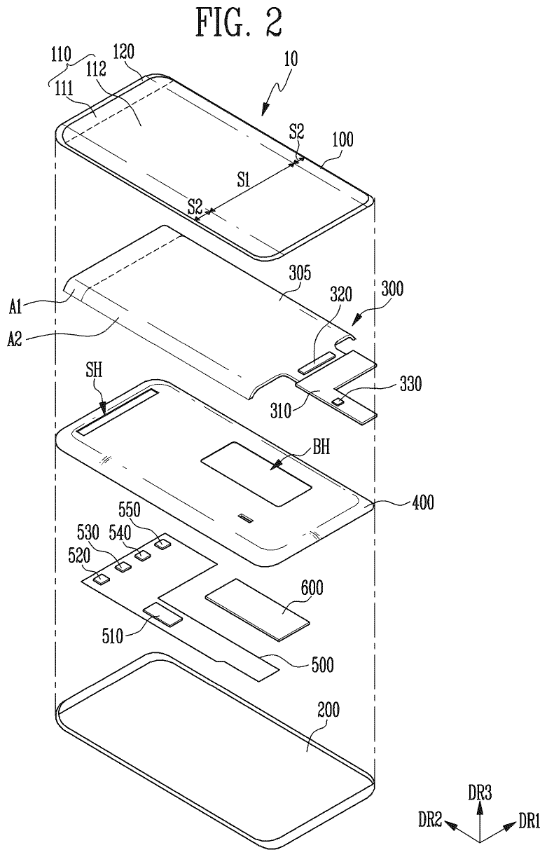

FIG. 2 is an exploded perspective view of the display device shown in FIG. 1, according to an embodiment.

In an embodiment and referring to FIG. 2, the display device 10 may further include a display module 300, a bracket 400, and a main circuit board 500, in addition to the cover window 100 and the lower cover 200. The cover window 100 and the lower cover 200 may be configured similarly to the cover window 100 and the lower cover 200 described with reference to FIG. 1. Hereinafter, an overlapping description is omitted.

In an embodiment and as described above, the display module 300, the bracket 400, and the main circuit board 500 may be disposed in the empty space provided therein by combining the cover window 100 and the lower cover 200 to each other.

In an embodiment, the display module 300 may include a display panel 305, a display circuit board 310, a display driving circuit 320, and a sensing driver 330.

The display panel 305 may be disposed under the cover window 100 to overlap the transmission cover portion 110 of the cover window 100. A portion of the display panel 305 may be disposed to correspond to the first surface S1 of the cover window 100, and another portion of the display panel 305 may be disposed to correspond to the second surface S2 of the cover window 100. According to this embodiment, light may be output from the display panel 305 not only through the first surface S1 but also the second surface S2.

In an embodiment, the display panel 305 may include a first area A1 overlapping the first sub-transmission cover portion 111 of the cover window 100 in a plan view, and a second area A2 overlapping the second sub-transmission cover portion 112.

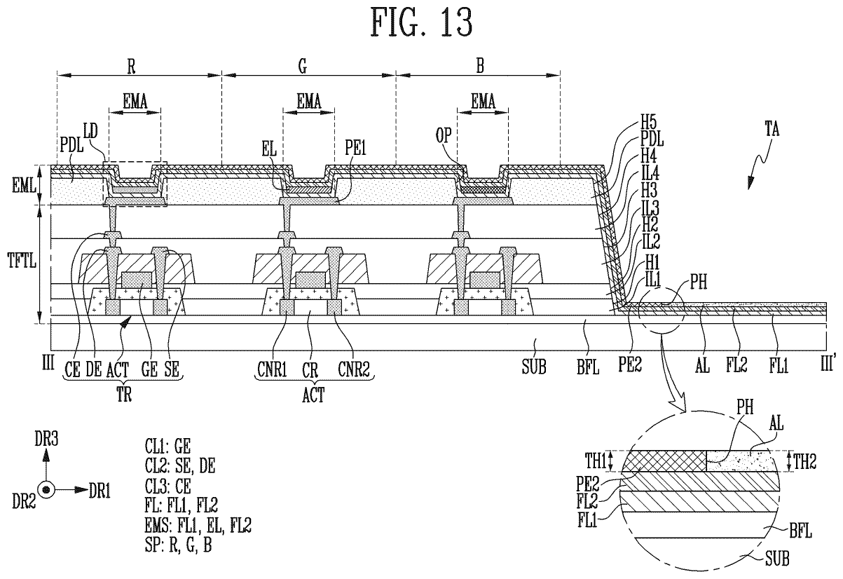

The display panel 305 may include a light emitting element (refer to LD of FIG. 13) that may emit light when an electrical signal is provided. According to an embodiment, the display panel 305 may be at least one of an organic light emitting display panel including an organic light emitting diode, a micro light emitting diode display panel including a micro light emitting diode, a quantum dot light emitting display panel including a quantum dot light emitting diode, and an inorganic light emitting display panel including an inorganic light emitting diode to which an inorganic semiconductor is applied, but is not limited to the examples described above. Hereinafter, for convenience of description, the invention is described based on an embodiment where the display panel 305 is an organic light emitting display panel including an organic light emitting diode.

In an embodiment, the display circuit board 310 and the display driving circuit 320 may be disposed on one side of the display panel 305.

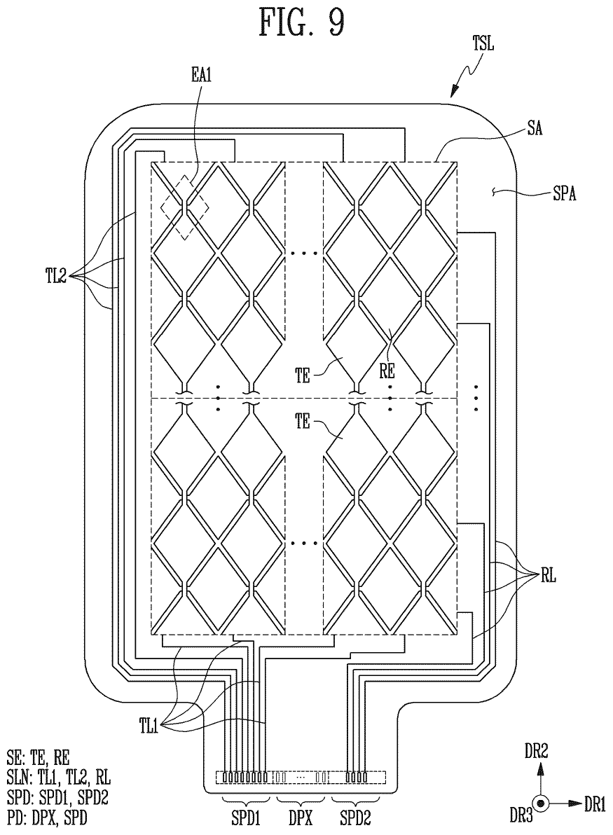

One end of the display circuit board 310 may be attached on pads (refer to PD) of FIG. 9 provided on one side of the display panel 305 using an anisotropic conductive film. The display circuit board 310 may be a flexible printed circuit board FPCB that may be bent, but is not limited thereto.

In an embodiment, the display driving circuit 320 may receive control signals and power voltages through the display circuit board 310, and may generate and output signals and voltages for driving the display panel 305. The display driving circuit 320 may supply data voltages to data lines. In addition, the display driving circuit 320 may supply the power voltage to a power line and supply scan control signals to a scan driver. The display driving circuit 320 may be configured as an integrated circuit (IC). The display driving circuit 320 may be disposed on the display panel 305. For example, the display driving circuit 320 may be attached on the display panel 305 using a chip on glass (COG) method, a chip on plastic (COP) method, or an ultrasonic method. In another embodiment, the display driving circuit 320 may be disposed on the display circuit board 310.

In an embodiment, the sensing driver 330 may be disposed on the display circuit board 310. Similarly to the display driving circuit 320, the sensing driver 330 may be configured as an integrated circuit and may be attached on the display circuit board 310.

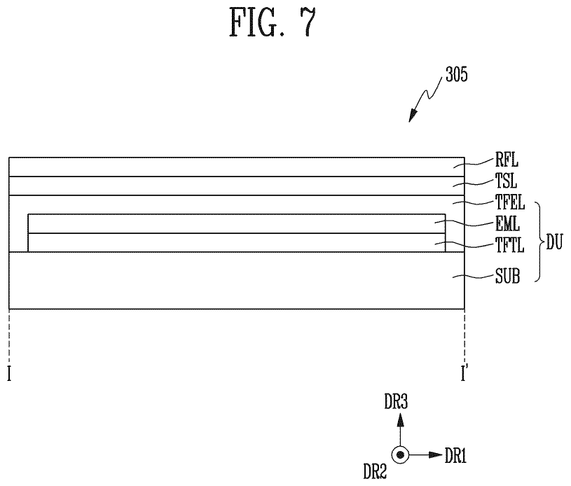

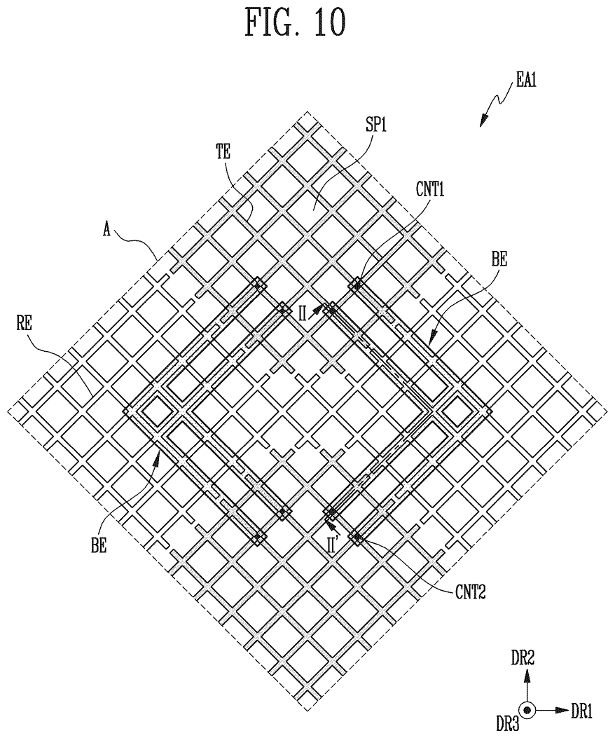

The sensing driver 330 may be electrically connected to sensing electrodes (refer to SE) of FIG. 10 of touch sensing layer (refer to TSL) of FIG. 7 of the display panel 305 through the display circuit board 310. The touch sensing layer TSL may obtain touch input information applied from an outside. Specifically, the sensing driver 330 may apply driving signals to the sensing electrodes SE and measure mutual capacitance values of the sensing electrodes SE. The driving signal may be a signal having a plurality of driving pulses. The sensing driver 330 may determine whether the user is touching, being in proximity, or the like, based on the mutual capacitance values.

In an embodiment, the bracket 400 may be disposed under the display module 300 and may include at least one of plastic or metal, but is not limited thereto.

The bracket 400 may include a sensor hole SH and a battery hole BH. Lower panel sensors 520, 530, 540, and 550 may be disposed in the sensor hole SH, and a battery 600 may be disposed in the battery hole BH. The sensor hole SH and the battery hole BH may have a through-hole shape formed along a thickness direction of the bracket 400. The sensor hole SH may overlap the first area Al of the display panel 305 in a plan view.

In an embodiment, the main circuit board 500 and the battery 600 may be disposed under the bracket 400, where the main circuit board 500 may be a printed circuit board (PCB) or a flexible printed circuit board.

In an embodiment, the main circuit board 500 may include a main processor 510 and lower panel sensors 520, 530, 540, and 550. The panel lower sensors 520, 530, 540, and 550 may be disposed on an upper surface of the main circuit board 500. The panel lower sensors 520, 530, 540, and 550 may overlap the transmission cover portion 110 of the cover window 100 and the first area A1 of the display panel 305 in a plan view.

In an embodiment, the main processor 510 may control the display device 10. The main processor 510 may be implemented as a central processing unit CPU or a device similar thereto according to hardware, software, or a combination thereof. For example, the main processor 510 may output digital video data to the display driving circuit 320 through the display circuit board 310 so that the display panel 305 displays an image.

In addition, the main processor 510 may receive sensing data from the sensing driver 330, determine a user's touch coordinate, and then execute an application indicated by an icon displayed at the user's touch coordinate. Moreover, the main processor 510 may control the display device 10 according to sensing signals input from the lower panel sensors 520, 530, 540, and 550.

In an embodiment, the panel lower sensors 520, 530, 540, and 550 may obtain electrical information based on information (for example, light intensity, emission frequency, light spectrum, temperature, and the like) applied from an outside source. For example, the panel lower sensors 520, 530, 540, and 550 may be configured of a proximity sensor 520, an illuminance sensor 530, an iris sensor 540, and a camera device 550, respectively.

In an embodiment, the proximity sensor 520 may sense whether an object is positioned close to an upper surface of the display device 10. The proximity sensor 520 may include a light receiver receiving light reflected by an object that outputs light. The proximity sensor 520 may determine whether an object positioned close to the upper surface of the display device 10 exists according to a light amount reflected by the object. Accordingly, the proximity sensor 520 may generate a proximity sensor signal and output the proximity sensor signal to the main processor 510.

In an embodiment, the illuminance sensor 530 may sense a brightness of the upper surface of the display device 10. To this end, the illuminance sensor 530 may include a resistor of which a resistance value changes according to a brightness of incident light. The illuminance sensor 530 may determine the brightness of the upper surface of the display device 10 according to a change of the resistance value. The illuminance sensor 530 may generate an illuminance sensor signal according to the brightness of the upper surface of the display device 10 and output the illuminance sensor signal to the main processor 510.

In an embodiment, the iris sensor 540 may sense whether an image obtained by capturing a user's iris is equal to an iris image stored in a memory in advance. Accordingly, the iris sensor 540 may generate an iris sensor signal and output the iris sensor signal to the main processor 510.

In an embodiment, the camera device 550 may process an image frame such as a still image or a moving image obtained by an image sensor in a camera mode and output the image frame to the main processor 510. The camera device 550 may include an image sensor that receives light provided through the transmission cover portion 110 of the first area A1. As described above, in FIG. 2, the proximity sensor 520, the illuminance sensor 530, the iris sensor 540, and the camera device 550 are shown as the panel lower sensors 520, 530, 540, and 550, but are not necessarily limited thereto. For example, in another embodiment, an infrared sensor, an ultrasonic sensor, and/or the like may be further included.

In an embodiment, the battery 600 may not overlap the main circuit board 500 in a plan view. The battery 600 may overlap the battery hole BH of the bracket 400.

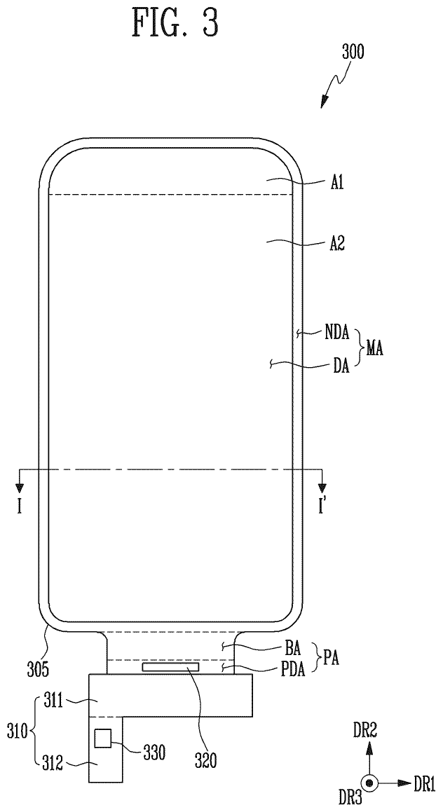

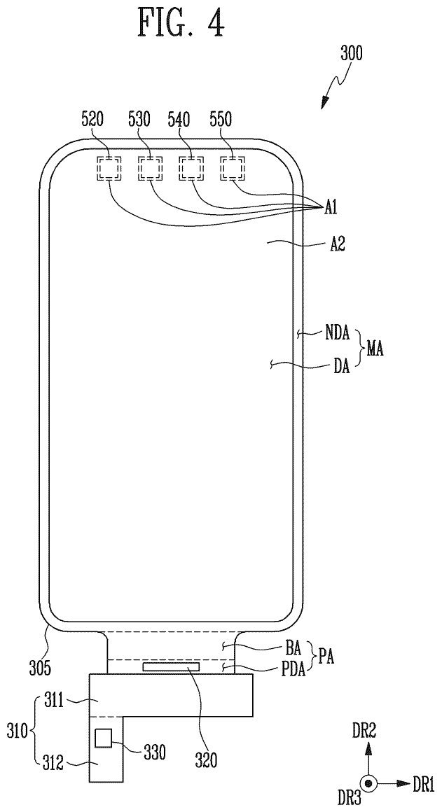

FIG. 3 is a plan view illustrating a display module, according to an embodiment. FIG. 4 is a plan view illustrating a display module, according to another embodiment.

In an embodiment, the display panel 305 may include a main area MA and a protrusion area PA protruding from one side of the main area MA.

The main area MA may include a display area DA that displays an image and a non-display area NDA which is a surrounding area of the display area DA.

In an embodiment, the display area DA may include a first area A1 and a second area A2, which is a remaining area except for the first area A1. The first area A1 and the second area A2 may be provided in various forms. For example, as shown in FIG. 3, the first area A1 may be partitioned from the second area A2 along the second direction DR2. In another embodiment, as shown in FIG. 4, the first area A1 may be formed in plural numbers and surrounded by the second area A2. However, a disposition structure of the first area A1 and the second area A2 is not limited to the examples described above, and each may be disposed in at least a portion of the display area DA.

In an embodiment and referring to FIG. 4, the number of first areas A1 may correspond to the number of lower panel sensors 520, 530, 540, and 550, where each of the panel lower sensors 520, 530, 540, and 550 may overlap one of the first areas A1 in a plan view.

In an embodiment, the area of the first area A1 may be different from the area of the second area A2. For example, the area of the first area A1 may be less than the area of the second area A2, but is not necessarily limited thereto.

In an embodiment, the protrusion area PA may protrude from one side of the main area MA. For example, referring to FIGS. 3 and 4 together, the protrusion area PA may protrude from a lower side of the main area MA. Based on the first direction DR1, a length of the protrusion area PA may be less than a length of the main area MA.

In an embodiment, the protrusion area PA may include a bending area BA and a pad area PDA. In this embodiment, the pad area PDA may be disposed on one side of the bending area BA, and the main area MA may be disposed on another side of the bending area BA. For example, the bending area BA may be disposed between the main area MA and the pad area PDA.

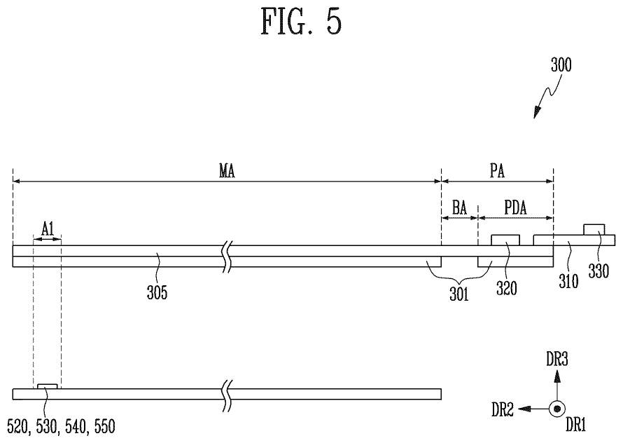

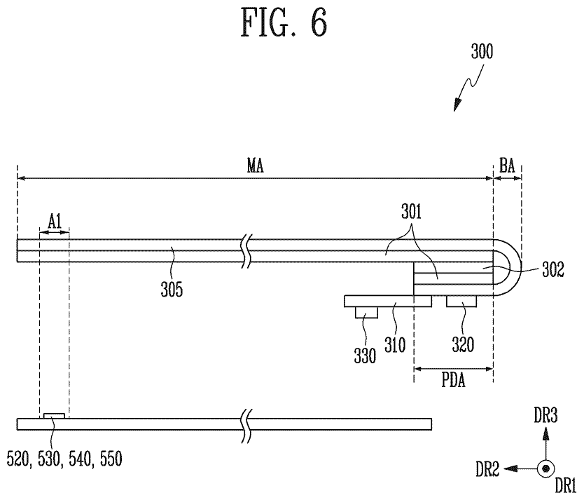

FIG. 5 is a side view of the display panel illustrating an aspect before the protrusion area of the display panel shown in FIG. 4 is bent, according to an embodiment. FIG. 6 is a side view of the display panel illustrating an aspect in which the protrusion area of the display panel shown in FIG. 5 is bent, according to an embodiment.

In an embodiment and as described with reference to FIG. 4 and referring to FIGS. 5 and 6, the first area A1 of the display panel 305 may overlap the lower panel sensors 520, 530, 540, and 550 in a plan view. In other words, the proximity sensor 520, the illuminance sensor 530, the iris sensor 540, and the camera device 550 may overlap the first area A1 of the display panel 305 in a plan view.

In an embodiment, the display panel 305 may include a flexible material that may be bent, folded, or rolled. As shown in FIG. 5, when the display panel 305 is not yet bent, one surface of the pad area PDA may face upward. Meanwhile, as shown in FIG. 6, the display panel 305 may be bent in a thickness direction (that is, a third direction DR3) in the bending area BA. When the display panel 305 is bent as described above, one surface of the pad area PDA of the display panel 305 may face downward. Accordingly, since the pad area PDA is disposed under the main area MA, the pad area PDA may overlap the main area MA in a plan view.

In an embodiment, a panel protection film 301 may be disposed under the display panel 305 and may be attached to a lower surface of the display panel 305 through an adhesive member. The adhesive member may be a pressure sensitive adhesive (PSA).

The panel protection film 301 may include a light absorption member (not shown) for absorbing light incident from the outside, a buffer member (not shown) for absorbing shock from the outside, a heat dissipation member (not shown) for efficiently dissipating heat of the display panel 305, or the like.

In an embodiment, the light absorption member may be disposed under the display panel 305, where the light absorption member may block transmission of light to prevent configurations disposed under the light absorption member, such as the display circuit board 310, from being recognized to the user from an upper portion of the display panel 305. The light absorption member may include a light absorbing material such as black pigment or black dye.

In an embodiment, the buffer member may be disposed under the light absorption member, where the buffer member may prevent damage to the display panel 305 by absorbing external shock. The buffer member may be configured of a single layer or multiple layers. For example, the buffer member may be formed of a polymer resin such as polyurethane, polycarbonate, polypropylene, or polyethylene, or may be formed by including a material having elasticity such as a sponge formed by foaming and molding rubber, a urethane-based material, or an acrylic-based material. The buffer member may also be referred to as a cushion layer.

In an embodiment, the heat dissipation member may be disposed under the buffer member and may include a first heat dissipation layer (not shown) including graphite, a carbon nanotube, or the like and a second heat dissipation layer (not shown) formed of a metal thin film such as copper, nickel, ferrite, and silver, which may shield an electromagnetic wave and has excellent thermal conductivity.

In an embodiment, in order to allow the display panel 305 to be easily bent, the panel protection film 301 may not be disposed in the bending area BA of the display panel 305, as shown in FIG. 5. As shown in FIG. 6, since the pad area PDA is disposed under the main area MA as the display panel 305 is bent in the bending area BA, the pad area PDA may overlap the main area MA. Accordingly, the panel protection film 301 disposed in the main area MA of the display panel 305 and the panel protection film 301 disposed in the pad area PDA of the display panel 305 may be attached by an adhesive member 302. The adhesive member 302 may be a pressure sensitive adhesive.

In an embodiment, although not shown in the drawing, a panel lower cover (not shown) may be further disposed under the panel protection film 301. The panel lower cover may be disposed under the panel protection film 301 disposed in the main area MA and may not be disposed in the bending area BA and pad area PDA. According to an embodiment, when the display panel 305 is bent in the bending area BA and the pad area PDA is disposed under the main area MA, at least a portion of the panel lower cover may overlap the pad area PDA.

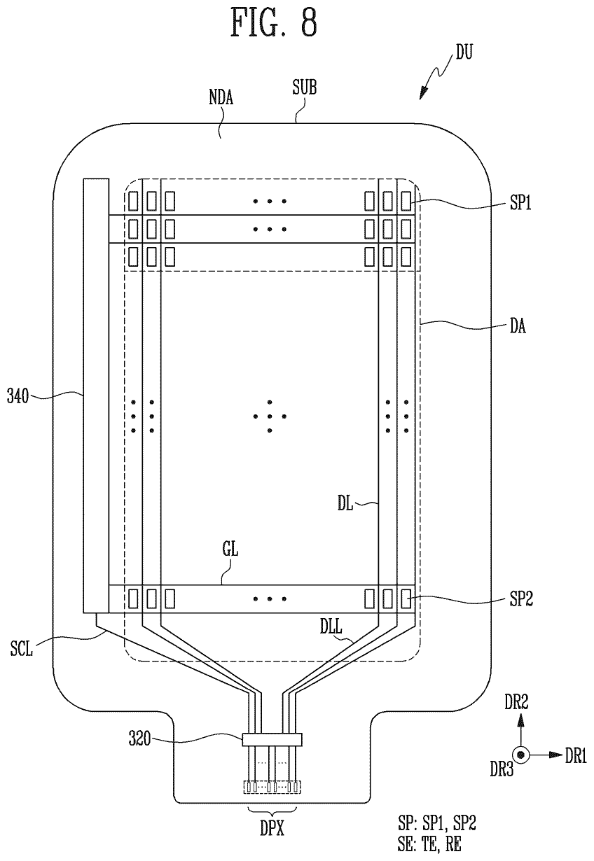

In an embodiment, pads (refer to PD of FIG. 9) to which the display circuit board 310 and the display driving circuit 320 are electrically connected may be disposed in the pad area PDA of the display panel 305. The pads PD may include display pads electrically connected to the display driving circuit 320 through the scan line and the power line (refer to DPX of FIGS. 8 and 9), and a sensing pad (refer to SPD of FIG. 9) electrically connecting the sensing electrodes (refer to SE of FIG. 9) and the sensing driver 330 through a sensing line (refer to SLN of FIG. 9).

FIG. 7 is a cross-sectional view taken along line I-I′ of FIG. 3, according to an embodiment.

In an embodiment and referring to FIG. 7, the display panel 305 may include a display unit DU, a touch sensing layer TSL, and an anti-reflection layer RFL. The display unit DU may include a substrate SUB, a thin film transistor layer TFTL, a light emitting element layer EML, and a thin film encapsulation layer TFEL.

The substrate SUB may be configured of an insulating material such as glass, quartz, or polymer resin. The substrate SUB may be a rigid substrate or a flexible substrate capable of bending, folding, rolling, or the like. When the substrate SUB is a flexible substrate, the substrate SUB may be formed of polyimide, but is not limited thereto.

The thin film transistor layer TFTL may be disposed on the substrate SUB. In the thin film transistor layer TFTL, scan lines, data lines, power lines, scan control lines, routing lines connecting the pads and the data lines, and the like as well as thin film transistors TR of each of pixels SP may be formed. Each of the thin film transistors TR may include a gate electrode (refer to GE of FIG. 13), a semiconductor layer (refer to ACT of FIG. 13), a source electrode (refer to SE of FIG. 13), and a drain electrode (refer to DE of FIG. 13).

The thin film transistor layer TFTL may be disposed in the display area DA and the non-display area NDA. For example, in an embodiment, the thin film transistors, the scan lines, the data lines, and the power lines of the thin film transistor layer TFTL may be disposed in the display area DA.

The light emitting element layer EML may be positioned on the thin film transistor layer TFTL.

The light emitting element layer EML may include pixels (refer to SP of FIG. 13) including a first pixel electrode (refer to PEL of FIG. 13), a light emitting structure (refer to EMS of FIG. 13), and a second pixel electrode (refer to PE2 of FIG. 13), and a pixel defining layer (refer to PDL of FIG. 13) defining an emission area EMA of the pixels SP. The light emitting structure EMS may be an organic light emitting layer including an organic material. In this embodiment, the light emitting structure EMS may include a hole transporting layer, an organic light emitting layer, and an electron transporting layer.

In an embodiment, when a predetermined voltage is applied to the first pixel electrode PE1 through the thin film transistor TR of the thin film transistor layer TFTL and a cathode voltage is applied to the second pixel electrode PE2, a hole and an electron may move to the light emitting structure EMS through the hole transporting layer and the electron transporting layer, respectively, and may combine with each other in the light emitting structure EMS to emit light. The pixels SP of the light emitting element layer EML may be disposed in the display area DA.

The thin film encapsulation layer TFEL may be disposed on the light emitting element layer EML.

The thin film encapsulation layer TFEL may serve to prevent oxygen or moisture from penetrating into the light emitting element layer EML. To this end, the thin film encapsulation layer TFEL may include at least one inorganic insulating layer. The inorganic insulating layer may include at least one of metal oxides such as silicon oxide (SiOx), silicon nitride (SiNx), silicon oxynitride (SiOxNy), and aluminum oxide (AlOx). However, a material of the inorganic insulating layer is not limited thereto.

In addition, the thin film encapsulation layer TFEL may serve to protect the light emitting element layer EML from a foreign substance such as dust. To this end, the thin film encapsulation layer TFEL may include at least one organic insulating layer. The organic insulating layer may include at least one of, for example, acrylic resin, epoxy resin, phenolic resin, polyamide resin, polyimide resin, unsaturated polyester resin, poly-phenylene ether resin, poly-phenylene sulfide resin, and benzocyclobutene resin. However, a material of the organic insulating layer is not limited thereto.

The thin film encapsulation layer TFEL may be disposed throughout the display area DA and the non-display area NDA. Specifically, the thin film encapsulation layer TFEL may be disposed to cover the light emitting element layer EML and the thin film transistor layer TFTL in the display area DA and the non-display area NDA.

In an embodiment, the touch sensing layer TSL may be disposed on the thin film encapsulation layer TFEL.

The touch sensing layer TSL may include sensing electrodes (refer to SE of FIG. 9), a sensing pad (refer to SPD of FIG. 9), and a sensing line (refer to SLN of FIG. 9). The touch sensing layer TSL is described in detail with reference to FIGS. 10 to 12 below.

In an embodiment, the anti-reflection layer RFL may be positioned on the touch sensing layer TSL and may serve to block external light reflection. To this end, the anti-reflection layer RFL may include a light blocking layer (not shown) formed of a light blocking material. Accordingly, since a separate polarizer may be omitted, a luminance decrease of the display device 10 may be prevented and a thickness of the display panel 305 may be minimized.

FIG. 8 is a plan view illustrating the display unit of the display panel shown in FIG. 7, according to an embodiment.

For convenience of description, FIG. 8 shows an embodiment of the display unit DU based on the pixels SP, a scan line GL, a data line DL, a scan control line SCL, a fan out line DLL, a display driving circuit 320, a scan driver 340, and display pads DPX of the display unit DU.

In an embodiment and referring to FIG. 8, the pixel SP, the scan line GL, and the data line DL may be disposed in the display area DA.

In an embodiment, the pixel SP may include a first pixel SP1 disposed in the first area A1 (refer to A1 of FIG. 3 or 4) and a second pixel SP2 disposed in the second area A2 (refer to A2 of FIG. 3 or 4). The first pixel SP1 and the second pixel SP2 are described in more detail with reference to FIG. 12 below.

In an embodiment, the scan line GL may extend in the first direction DR1 and may be disposed side by side along the second direction DR2. The data line DL may extend in the second direction DR2 crossing the first direction DR1 and may be disposed side by side along the first direction DR1.

In an embodiment, each of the first pixel SP1 and the second pixel SP2 may be electrically connected to at least one of the scan lines GL and one of the data lines DL. Each of the first pixel SP1 and the second pixel SP2 may include a thin film transistor (refer to TR of FIG. 13) including a driving transistor and at least one switching transistor, a light emitting element (refer to DL of FIG. 13), and a capacitor (not shown).

In an embodiment, each of the first pixel SP1 and the second pixel SP2 may receive a data voltage of the data line DL when a scan signal is applied from the scan line GL, and may emit light by supplying a driving current to the light emitting element LD according to the data voltage applied to a gate electrode (refer to GE of FIG. 13).

The light emitting element LD is described as an organic light emitting element including the first pixel electrode (refer to PEL of FIG. 13), the light emitting structure (refer to EMS of FIG. 13), and the second pixel electrode (refer to PE2 of FIG. 13), but is not limited thereto. That is, the light emitting element may also be implemented as a quantum dot light emitting element including the first pixel electrode PE1, a quantum dot light emitting layer (not shown), and the second pixel electrode PE2, an inorganic light emitting element including the first pixel electrode PE1, an inorganic semiconductor (not shown), and the second pixel electrode PE2, or an ultra-small light emitting element including an ultra-small light emitting diode.

In an embodiment, the display driving circuit 320 is connected to the display pads DPX and receives digital video data and timing signals. The display driving circuit 320 converts the digital video data into analog positive/negative polarity data voltages and supplies the analog positive/negative polarity data voltages to the data lines DL through the fan out lines DLL. In addition, the display driving circuit 320 generates and supplies a scan control signal for controlling the scan driver 340 through a plurality of scan control lines SCL. Pixels SP to which the data voltages are to be supplied are selected by scan signals of the scan driver 340, and the data voltages are supplied to the selected pixels SP.

In an embodiment, the scan driver 340 may be connected to the display driving circuit 320 through a plurality of scan control lines SCL and may receive the scan control signal from the display driving circuit 320. The scan driver 340 may generate the scan signals according to the scan control signal and supply the scan signals to the scan line GL.

FIG. 9 is a plan view illustrating the touch sensing layer shown of FIG. 7, according to an embodiment.

In an embodiment and referring to FIG. 9, the touch sensing layer TSL may include a sensing area SA for sensing a user's touch and a sensing peripheral area SPA disposed around the sensing area SA. The sensing area SA may overlap the display area DA of the display unit DU, and the sensing peripheral area SPA may overlap the non-display area NDA (refer to FIG. 8 together).

In an embodiment, the touch sensing layer TSL may be implemented in one of a capacitive type, an electro-magnetic type, and an optical type. When the touch sensing layer TSL is implemented as the capacitive type, the sensing electrodes SE of the touch sensing layer TSL may be configured as a self-capacitive type, a mutual-capacitive type, or the like.

In an embodiment, the sensing electrodes SE may include transmitter electrodes TE providing a first sensing signal (for example, a driving signal or a transmission signal), and receiver electrodes RE providing a second sensing signal (for example, an output signal or a reception signal).

In an embodiment, the transmitter electrodes TE may extend along the second direction DR2 and may be disposed side by side along the first direction DR1. For example, the respective transmitter electrodes TE may form a transmitter column.

In an embodiment, the receiver electrodes RE may extend along the first direction DR1 and may be disposed side by side along the second direction DR2. For example, the respective receiver electrodes RX may form a receiver row.

In an embodiment, the transmitter electrodes TE and the receiver electrodes RE may be electrically separated from each other and may be disposed to be spaced apart from each other.

In an embodiment, the sensing pad SPD and a sensing line SLN may be disposed in the sensing peripheral area SPA.

In an embodiment, the sensing pad SPD may be disposed on one side of the touch sensing layer TSL and may include first sub-sensing pads SPD1 and second sub-sensing pads SPD2. The first sub-sensing pads SPD1 may be disposed on one side of the display pads DPX, and the second sub-sensing pads SPD2 may be disposed on another side of the display pads DPX, but are not limited thereto.

In an embodiment, the sensing line SLN may include first driving lines TL1, second driving lines TL2, and sensing lines RL, where the first driving lines TL1 and the second driving lines TL2 may be connected to the transmitter electrodes TE, and the sensing lines RL may be connected to the receiver electrodes RE.

The first driving lines TL1 may be connected to a portion of the transmitter electrodes TE disposed on one side of the sensing area SA, and the second driving lines TL2 may be electrically connected to another portion of the transmitter electrodes TE disposed on another side of the sensing area SA. Here, one side of the sensing area SA may refer to a lower side of the sensing area SA, and another side of the sensing area SA may refer to an upper side of the sensing area SA. That is, the upper side and the lower side of the sensing area SA may be sides that are facing each other. For example, transmitter electrodes TE disposed at a lower end of the sensing area SA among the transmitter electrodes TE electrically connected along the second direction DR2 may be electrically connected to the first driving lines TL1, and transmitter electrodes TE disposed at an upper end of the sensing area SA among the transmitter electrodes TE may be electrically connected to the second driving lines TL2.

The second driving lines TL2 may be electrically connected to the transmitter electrodes TE at an upper side of the sensing area SA via a left outer side of the sensing area SA. One end of the first driving lines TL1 and the second driving lines TL2 may be electrically connected to the transmitter electrodes TE, and another end of the first driving lines TL1 and the second driving lines TL2 may be electrically connected to the first sub-sensing pads SPD1. According to this embodiment, the sensing driver 330 may be electrically connected to the transmitter electrodes TE through the first sub-sensing pads SPD1, the first driving lines TL1, and the second driving lines TL2.

In an embodiment, the receiver electrodes RE disposed on one side of the sensing area SA may be electrically connected to the sensing lines RL. For example, among the receiver electrodes RE electrically connected along the first direction DR1, the receiver electrodes RE disposed at a right end may be electrically connected to the sensing line RL. One end of the sensing line RL may be electrically connected to the receiver electrodes RE, and another end of the sensing line RL may be electrically connected to the second sub-sensing pads SPD2. According to this embodiment, the sensing driver 330 may be electrically connected to the receiver electrodes RE through the second sub-sensing pads SPD2 and the sensing lines RL.

In an embodiment, although not shown in the drawing, a ground line (not shown) may be further disposed outside the sensing line SLN, where the ground line may be disposed on the outermost edge of the touch sensing layer TSL and where a ground voltage may be applied to the ground line. Accordingly, when static electricity is applied from an outside source, the static electricity may be discharged to the ground line. One end of the ground line may be electrically connected to the sensing pad SPD.

In addition, in an embodiment, a guard line (not shown) may be further disposed between the sensing line SLN and the ground line. According to this embodiment, the guard line may serve to minimize coupling between the first driving lines TL1, the second driving lines TL2, and the sensing lines RL, or minimize coupling between the first driving lines TL1, the second driving lines TL2, and the sensing lines RL, and the ground line. One end of the guard line may be electrically connected to the first sub-sensing pads SPD1 and the second sub-sensing pads SPD2.

FIG. 10 is an enlarged view of a portion EA1 of FIG. 9, according to an embodiment.

In an embodiment and referring to FIG. 10, transmitter electrodes TE disposed adjacent to each other along the second direction DR2 may be electrically connected to each other by a bridge electrode BE. Transmitter electrodes TE disposed adjacent to each other along the first direction DR1 may be insulated from each other. In addition, receiver electrodes RE disposed adjacent to each other along the first direction DR1 may be electrically connected to each other, and receiver electrodes TE disposed adjacent to each other along the second direction DR2 may be electrically insulated from each other. According to this structure, a mutual capacitance may be formed in an area where the transmitter electrodes TE and the receiver electrodes RE intersect each other. The sensing driver 330 may determine touch or not of the user by sensing a voltage charged in the mutual capacitance. The transmitter electrodes TE and the receiver electrodes RE may be configured in a mesh or network form.

In an embodiment, the bridge electrodes BE may electrically connect the transmitter electrodes TE disposed adjacent to each other along the second direction DR2 through first contact holes CNT1 and second contact holes CNT2, respectively. One end of the bridge electrode BE may be electrically connected to one transmitter electrode TE among the transmitter electrodes TE disposed adjacent to each other along the second direction DR2 through the first contact hole CNT1. In addition, another end of the bridge electrode BE may be electrically connected to another transmitter electrode TE among the transmitter electrodes TE disposed adjacent to each other along the second direction DR2 through the second contact hole CNT2.

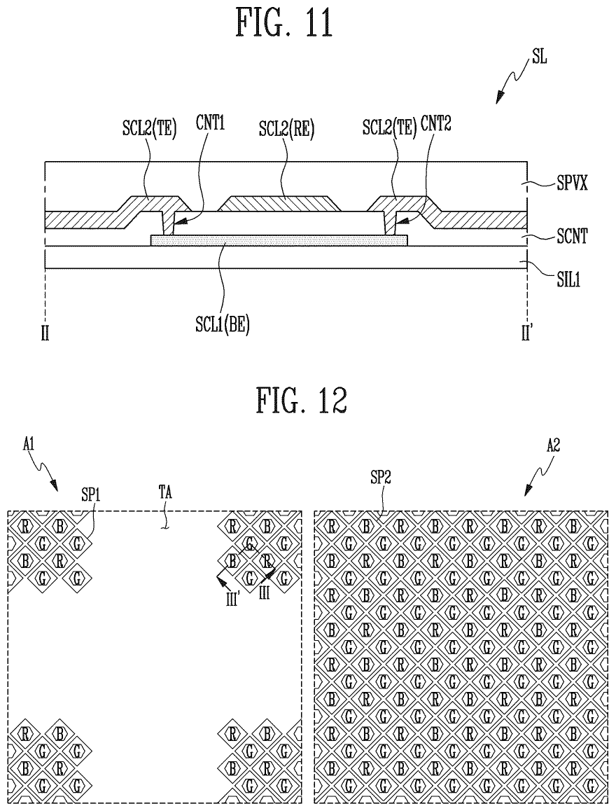

FIG. 11 illustrates an embodiment in which the transmitter electrodes TE are electrically connected to each other by a pair of bridge electrodes BE, but the invention is not limited thereto. For example, the bridge electrode BE may include a plurality of sub-bridge electrodes configured of several pairs.

FIG. 11 is a cross-sectional view taken along line II-II′ of FIG. 10, according to an embodiment.

In an embodiment and referring to FIG. 11, the touch sensing layer TSL includes a first sensing insulating layer SIL1, a sensing contact layer SCNT, a sensing protective layer SPVX, a first sensing conductive layer SCL1, and a second sensing conductive layer SCL2. Each of the above-described layers may be formed of a single layer, but may be formed of multiple layers including a plurality of layers. In an embodiment, another layer may also be disposed between each of the layers.

The first sensing insulating layer SIL1 may include an inorganic insulating layer. However, the invention is not limited thereto, and the first sensing insulating layer SIL1 may be formed of an organic insulating layer or may have a structure in which an inorganic insulating layer and an organic insulating layer are alternately stacked.

The inorganic insulating layer may include at least one of metal oxides such as silicon oxide (SiOx), silicon nitride (SiNx), silicon oxynitride (SiOxNy), and aluminum oxide (AlOx). However, a material of the inorganic insulating layer is not limited thereto.

The organic insulating layer may include at least one of, for example, acrylic resin, epoxy resin, phenolic resin, polyamide resin, polyimide resin, unsaturated polyester resin, poly-phenylene ether resin, poly-phenylene sulfide resin, and benzocyclobutene resin. However, a material of the organic insulating layer is not limited thereto.

The first sensing conductive layer SCL1 may be disposed on the first sensing insulating layer SIL1 and may include molybdenum, titanium, copper, aluminum, and an alloy thereof.

The first sensing conductive layer SCL1 may include the bridge electrodes BE described above. The first sensing conductive layer SCL1 forming the bridge electrodes BE may have a mesh shape as described above. According to this embodiment, as the bridge electrodes BE are disposed to overlap the pixel defining layer (refer to PDL of FIG. 13) to be described later, an aperture ratio of the pixel may be prevented from being decreased, and the bridge electrodes BE may not be recognized to the user.

The sensing contact layer SCNT may be disposed on the first sensing conductive layer SCL1 and may insulate the first sensing conductive layer SCL1 and the second sensing conductive layer SCL2 from each other.

The sensing contact layer SCNT may include the same material as the first sensing insulating layer SIL1 described above, or may include one or more materials selected from the materials exemplified as a configuration material of the first sensing insulating layer SIL1. For example, in an embodiment, the sensing contact layer SCNT may include an inorganic insulating layer, but is not limited thereto.

A second sensing conductive layer SCL2 may be disposed on the sensing contact layer SCNT and may include the same material as the first sensing conductive layer SCL1 described above, or may include one or more materials selected from the materials exemplified as a configuration material of the first sensing conductive layer SCL1.

The second sensing conductive layer SCL2 may include the transmitter electrodes TE and the receiver electrodes RE described above. The transmitter electrodes TE may be electrically connected to the bridge electrodes BE through the first contact holes CNT1 and the second contact holes CNT2 exposing one end of the bridge electrodes BE by passing through the sensing contact layer SCNT.

The second sensing conductive layer SCL2 forming the transmitter electrodes TE and the receiver electrodes RE may have a mesh shape as described above. According to this embodiment, as the transmitter electrodes TE and the receiver electrodes RE are disposed to overlap the pixel defining layer (refer to PDL of FIG. 13) to be described later similarly to the bridge electrodes BE, an aperture ratio of the pixel may be prevented from being decreased and the transmitter electrodes TE and the receiver electrodes RE may not be recognized to the user.

The sensing protective layer SPVX may be disposed on the second sensing conductive layer SCL2. The sensing protective layer SPVX may be an organic insulating layer including an organic material. However, the invention is not limited thereto, and the sensing protective layer SPVX may be formed of an inorganic insulating layer, or may have a structure in which an organic insulating layer and an inorganic insulating layer are alternately stacked.

In an embodiment, FIGS. 10 to 12 illustrate a structure in which the sensing electrodes SE of the touch sensing layer TSL include the transmitter electrodes TE and the receiver electrodes RE, and driven in a mutual-capacitive type of two layers driven in a mutual-capacitive type sensing change amounts of mutual capacitances through the receiver electrodes RE after applying the driving signal to the transmitter electrodes TE, but the disclosure is not limited thereto. In an embodiment, the touch sensing layer TSL may include the transmitter electrodes TE and the receiver electrodes RE without the bridge electrodes BE and may be driven in a mutual-capacitive type of one layer driven in a mutual-capacitive type. For example, the touch sensing layer TSL may be driven in a self-capacitive type of one layer sensing a change amount of self-capacitances using one type of sensing electrode.

FIG. 12 is an enlarged plan view illustrating the first area and the second area shown of FIG. 4 in more detail, according to an embodiment.

In an embodiment and referring to FIG. 12, the first area A1 may include the first pixel SP1 and a transmission area TA surrounded by the first pixel SP1. The transmission area TA may be an area where the first pixel SP1 is not disposed and may not overlap the first pixel SP1 in a plan view. The transmission area TA may be disposed in the display area (refer to DA of FIGS. 3 and 4) outputting display and may provide a path through which light is provided from the outside.

The second area A2 may not include the transmission area TA. As the transmission area TA is partially formed in the first area A1, the number of first pixels SP1 per unit area of the first area A1 and the number of second pixels SP2 per unit area of the second area A2 may be different. For example, the number of first pixels SP1 per unit area of the first area A1 may be less than the number of second pixels SP2 per unit area of the second area A2. In addition, a size of the first pixel SP1 and a size of the second pixel SP2 may be different.

In an embodiment, the transmission area TA of the first area A1 may overlap the lower panel sensors 520, 530, 540, and 550 described with reference to FIG. 2 in a plan view. According to this embodiment, the transmission area TA may provide a path through which light from an upper portion of the display panel 305 may enter the lower panel sensors 520, 530, 540, and 550. To this end, a portion of layers configuring the thin film transistor layer TFTL and the light emitting element layer EML may be omitted in the transmission area TA. Therefore, even though the panel lower sensors 520, 530, 540, and 550 are disposed to overlap the display panel 305, sensing ability of the panel lower sensors 520, 530, 540, and 550 may be prevented or reduced from being decreased.

In an embodiment, each of the first pixel SP1 and the second pixel SP2 may include a first sub-pixel R emitting a first color, a second sub-pixel G emitting a second color, and a third sub-pixel B emitting a third color.

In FIG. 12, an embodiment where the first sub-pixel R and the third sub-pixel B are arranged alternately in a first column and the second sub-pixel G is sequentially arranged in a second column disposed adjacent to the first column is illustrated, but the invention is not limited thereto.

In addition, FIG. 12 illustrates a case where the first to third sub-pixels R, G, and B have the same shape and size, but the invention is not limited thereto. For example, each of the first to third sub-pixels R, G, and B may have shapes and sizes that are different from each other. In this embodiment, the size of the third sub-pixel B may be the largest and the size of the second sub-pixel G may be the smallest, but the invention is not limited thereto.

In addition, the first area A1 and the second area A2 shown in FIG. 12 merely shows an example of dispositions of the pixel SP, and disposition of the pixels SP defined in the first area A1 and the second area may be variously modified.

Hereinafter, the first area A1 is described in more detail with reference to FIGS. 13 to 21.

FIG. 13 is a cross-sectional view taken along line III-III′ of FIG. 12, according to an embodiment.

In an embodiment and referring to FIG. 13, the thin film transistor layer TFTL and the light emitting element layer EML may be disposed on the substrate SUB.

The thin film transistor layer TFTL may include a buffer layer BFL, a semiconductor layer ACT, a first insulating layer IL1, a first conductive layer CL1, a second insulating layer IL2, a second conductive layer CL2, a third insulating layer IL3, a third conductive layer CL3, and a fourth insulating layer IL4.

The buffer layer BFL may be disposed on the substrate SUB and may reduce or block penetration of a foreign substance, moisture, or external air from a lower portion of the substrate SUB and provide a flat surface on the substrate SUB. The buffer layer BFL may include an inorganic material such as oxide or nitride, an organic material, or an organic-inorganic composite, and may be configured of a single layer or multiple layer structure of an inorganic material and an organic material. In another embodiment, the buffer layer BFL may be omitted according to a material and a process condition of the substrate SUB.

In an embodiment, the semiconductor layer ACT may be disposed on the buffer layer BFL and may form a channel of the thin film transistor TR that transmits electrical signals to each pixel SP. The semiconductor layer ACT may include a channel region CR, a first contact region CNR1 connected to one end of the channel region CR, and a second contact region CNR2 connected to another end of the channel region CR.

The semiconductor layer ACT may include single crystal silicon, low-temperature polycrystalline silicon, amorphous silicon, or an oxide semiconductor. For example, when the semiconductor layer ACT is formed of polycrystalline silicon, an ion-doped semiconductor layer ACT may be conductive. Specifically, the channel region CR, the first contact region CNR1, and the second contact region CNR2 may be formed of a semiconductor layer that is not doped with an impurity or that is doped with an impurity. For example, the first contact region CNR1 and the second contact region CNR2 may be formed of a semiconductor layer doped with an impurity, and the channel region CR may be formed of a semiconductor layer that is not doped with an impurity. As an impurity, for example, a p-type impurity may be used, but the invention is not limited thereto. Due to this structure, the semiconductor layer ACT may include a source region and a drain region as well as the channel region of the thin film transistors TR. The source region and the drain region may be connected to both sides of each channel region CR. For example, one of the first contact region CNR1 and the second contact region CNR2 may be the source region, and the other may be the drain region.

The semiconductor layer ACT may include binary compounds (ABx), ternary compounds (ABxCy), and four-component compounds (ABxCyDz) containing, for example, indium (In), zinc (Zn), gallium (Ga), tin (Sn), titanium (Ti), aluminum (Al), hafnium (Hf), zirconium (Zr), magnesium (Mg), and the like. In addition, the semiconductor layer ACT may include indium tin zinc oxide (ITZO) or indium gallium zinc oxide (IGZO).

In an embodiment, the first insulating layer IL1 may be disposed on the semiconductor layer ACT, where the first insulating layer IL1 may be a gate insulating layer having a gate insulating function. The first insulating layer IL1 may not overlap the transmission area TA of the first area A1 in order to prevent a decrease of a transmittance of the transmission area TA of the first area A1, but the invention is not necessarily limited thereto.

The first insulating layer IL1 may be an inorganic insulating layer including an inorganic material. For example, the first insulating layer IL1 may be configured of a single layer or multiple layers including inorganic insulating material such as silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2).

In addition, the first insulating layer IL1 may include a first hole H1 corresponding to the transmission area TA. For example, in an embodiment, the first insulating layer IL1 may include the first hole H1 exposing a portion of an upper surface of the buffer layer or the substrate SUB (when the buffer layer is omitted) by removing a portion overlapping a transmission hole PH.

In an embodiment, the first conductive layer CL1 may be disposed on the first insulating layer IL1. The first conductive layer CL1 may include one or more metals selected from molybdenum (Mo), aluminum (Al), neodymium (Nd), aluminum neodymium (AlNd), platinum (Pt), palladium (Pd), silver (Ag), magnesium (Mg), gold (Au), nickel (Ni), iridium (Ir), chromium (Cr), calcium (Ca), titanium (Ti), tantalum (Ta), tungsten (W), and copper (Cu). The first conductive layer CL1 may be a single layer or multiple layers. For example, the first conductive layer CL1 may be formed in a stack structure of Ti/Al/Ti, Mo/Al/Mo, Mo/AlGe/Mo, or Ti/Cu.

The first conductive layer CL1 may include gate electrodes GE of the thin film transistors TR of the pixel SP and electrodes (not shown) of a maintenance capacitor.

In an embodiment, the second insulating layer IL2 may be disposed on the first conductive layer CL1, where the second insulating layer IL2 may cover the gate electrodes GE of the pixels SP. The second insulating layer IL2 may not overlap the transmission area TA of the first area A1 in a plan view in order to prevent a decrease of the transmittance of the transmission area TA of the first area A1, but is not necessarily limited thereto.

The second insulating layer IL2 may insulate the first conductive layer CL1 and the second conductive layer CL2 from each other. The second insulating layer IL2 may include the same material as the first insulating layer IL1, or may include one or more materials selected from among materials exemplified as a configuration material of the first insulating layer IL1.

In addition, the second insulating layer IL2 may include a second hole H2 corresponding to the transmission area TA. For example, in an embodiment, the second insulating layer IL2 may include the second hole H2 exposing a portion of the upper surface of the buffer layer BFL or the substrate (when the buffer layer is omitted) by removing a portion overlapping the transmission hole PH.

In an embodiment, the second conductive layer CL2 may be disposed on the second insulating layer IL2 and may include the same material as the first conductive layer CL1, or may include one or more materials selected from among materials exemplified as a configuration material of the first conductive layer CL1.

The second conductive layer CL2 may include source electrodes SE and drain electrodes DE of the pixels SP, where the source electrodes SE and the drain electrodes DE may be electrically connected to the first contact region CNR1 and the second contact region CNR2 through a contact hole passing through the first insulating layer IL1 and the second insulating layer IL2, respectively.

In an embodiment, the third insulating layer IL3 may be disposed on the second conductive layer CL2 and may cover the source electrodes SE and drain electrodes DE of the pixels SP. The third insulating layer IL3 may not overlap the transmission area TA of the first area A1 in a plan view in order to prevent a decrease of the transmittance of the transmission area TA of the first area A1, but is not necessarily limited thereto.

In an embodiment, the third insulating layer IL3 may be a via layer. The third insulating layer IL3 may be an inorganic insulating layer including an inorganic material or an organic insulating layer including an organic material. For example, the inorganic insulating layer may include at least one of metal oxides such as silicon oxide (SiOx), silicon nitride (SiNx), silicon oxynitride (SiOxNy), and aluminum oxide (AlOx). The organic insulating layer may include at least one of, for example, acrylic resin (polyacrylates resin), epoxy resin, phenolic resin, polyamides resin, polyimides resin, unsaturated polyesters resin, polyphenylene ethers resin, polyphenylene sulfides resin, and benzocyclobutene resin.

In addition, the third insulating layer IL3 may include a third hole H3 corresponding to the transmission area TA. For example, the third insulating layer IL3 may include the third hole H3 exposing a portion of the upper surface of the buffer layer BFL or the substrate (when the buffer layer is omitted) by removing a portion overlapping the transmission hole PH.

In an embodiment, the third conductive layer CL3 may be disposed on the third insulating layer IL3 and may include the same material as the second conductive layer CL2, or may include one or more materials selected from materials exemplified as a configuration material of the second conductive layer CL2.

The third conductive layer CL3 may include connection electrodes CE of the pixels SP, where the connection electrode CE may be electrically connected to the drain electrode DE through a contact hole passing through the third insulating layer IL3.

In an embodiment, the fourth insulating layer IL4 may be disposed on the third conductive layer CL3 and may cover the connection electrodes CE of the pixels SP. The fourth insulating layer IL4 may not overlap the transmission area TA of the first area A1 in a plan view in order to prevent a decrease of the transmittance of the transmission area TA of the first area A1, but is not necessarily limited thereto.

In an embodiment, the third conductive layer CL3 and/or the fourth insulating layer IL4 may be omitted. In this case, the third insulating layer IL3 may function as a via layer. For example, the first pixel electrode PE1 to be described later may be directly electrically connected to the drain electrode DE through a contact hole passing through the third insulating layer IL3 without passing through the connection electrode CE.

In an embodiment, the fourth insulating layer IL4 may be a via layer and may include the same material as the third insulating layer IL3, or may include one or more materials selected from materials exemplified as a configuration material of the third insulating layer IL3.

In addition, the fourth insulating layer IL4 may include a fourth hole H4 corresponding to the transmission area TA. For example, in an embodiment, the fourth insulating layer IL4 may include the fourth hole H4 exposing a portion of the upper surface of the buffer layer BFL or the substrate (when the buffer layer is omitted) by removing a portion overlapping the transmission hole PH.

In an embodiment, the light emitting element layer EML may be disposed on the thin film transistor layer TFTL.

The light emitting element layer EML may include the first pixel electrodes PE1, the pixel defining layer PDL, the light emitting structures EMS, the second pixel electrode PE2, and an auxiliary layer AL.

The light emitting element layer EML may be disposed over the display area DA, but a portion of the components of the light emitting element layer EML described above may not be disposed in the transmission area TA. Accordingly, the transmission area TA may provide a path through which light from an upper portion of the display panel 305 may enter the lower panel sensors 520, 530, 540, and 550. For example, in the drawing, an embodiment where the first pixel electrode PE1, the light emitting layer EL, and the pixel defining layer PDL among the components of the light emitting element layer EML are omitted, and a portion of the first functional layer FL1, the second functional layer FL2, and the second pixel electrode PE2, and the auxiliary layer AL are disposed in the transmission area TA is exemplified, but the invention is not necessarily limited thereto. In an embodiment, as the light emitting layer EL may also be disposed over the entire display area DA together with the first and second functional layers FL1 and FL2, a portion thereof may be disposed in the transmission area TA.

In an embodiment, the first pixel electrodes PE1 may be disposed on the thin film transistor layer TFTL. Each first pixel electrode PE1 may be electrically connected to the thin film transistors TR of each pixel SP. The first pixel electrode PE1 may contact the connection electrode CE through a contact hole passing through the fourth insulating layer IL4, and may be electrically connected to the drain electrode DE of the thin film transistor TR through the connection electrode CE. In an embodiment, the first pixel electrode PE1 may be an anode electrode of each pixel SP.

In an embodiment, in an upper light emitting structure which is emitting light in a direction facing the second pixel electrode PE2 based on the light emitting layer EL, the first pixel electrode PE1 may be formed of a metal material of which a reflectance is high such as a stack structure of aluminum and titanium (Ti/Al/Ti), a stack structure of aluminum and ITO (ITO/Al/ITO), an APC alloy, and a stack structure of APC alloy and ITO (ITO/APC/ITO). The APC alloy is an alloy of silver (Ag), palladium (Pd), and copper (Cu).

In an embodiment, in a lower light emitting structure which is emitting light in a direction facing the first pixel electrode PE1 based on the light emitting layer EL, the first pixel electrode PE1 may be formed of a transparent metal material such as ITO or IZO that may transmit light, or may be formed of a translucent metal material such as magnesium (Mg), silver (Ag), or an alloy of magnesium (Mg) and silver (Ag). When the first pixel electrode PE1 is formed of the translucent metal material, light output efficiency may be increased by a micro cavity.

In an embodiment, the pixel defining layer PDL may be disposed on the first pixel electrodes PE1 and may include an opening OP exposing a portion of each of the first pixel electrodes PE1. The opening OP of the pixel defining layer PDL may be understood as the emission areas EMA corresponding to first to third sub-pixels R, G, and B, respectively. For example, a size and a shape of the emission area EMA of each of the sub-pixels R, G, and B may be defined by the opening OP. The pixel defining layer PDL may increase a distance between an edge of the first pixel electrode PE1 and the second pixel electrode PE2 disposed on the first pixel electrode PE1 to prevent an arc or the like from occurring at the edge of the first pixel electrode PE1.

In an embodiment, the pixel defining layer PDL may include an inorganic material. In this case, the pixel defining layer PDL may include multiple stacked inorganic layers. For example, the pixel defining layer PDL may include silicon oxide (SiOx) and silicon nitride (SiNx). In other embodiments, the pixel defining layer PDL may include an organic material. For example, the pixel defining layer PDL may be formed in a method of a spin-coating or the like with an organic insulating material such as acryl resin, epoxy resin, phenolic resin, polyamide resin, polyimide resin, benzocyclobutene (BCB), and hexamethyldisiloxane (HMDSO).

In an embodiment, the pixel defining layer PDL may include a light absorbing material or may be coated with a light absorbing material to serve to absorb light input from the outside. For example, the pixel defining layer PDL may include a carbon-based black pigment, but is not limited thereto, and may include an opaque metal material such as chromium (Cr), molybdenum (Mo), an alloy of molybdenum and titanium (MoTi), tungsten (W), vanadium (V), niobium (Nb), tantalum (Ta), manganese (Mn), cobalt (Co), or nickel (Ni) having a high light absorption rate.

The pixel defining layer PDL may cover at least a portion of the thin film transistor layer TFTL and may block at least a portion of light that may be provided to the thin film transistor layer TFTL or the light emitting element layer EML through the transmission area TA.

In an embodiment, when an electrode is disposed in the thin film transistor layer TFTL, the pixel defining layer PDL may shield the electrode so that the electrode is not recognized from the outside. For example, in a plan view, the pixel defining layer PDL may overlap at least one electrode disposed in the thin film transistor layer TFTL. When the pixel defining layer PDL includes a material of which light absorption is excellent, shield performance for an individual configuration positioned in the thin film transistor layer TFTL may be further improved.

In addition, in an embodiment, the pixel defining layer PDL may include a fifth hole H5 corresponding to the transmission area TA, where the fifth hole H5 may expose a portion of the upper surface of the buffer layer BFL or the substrate SUB (when the buffer layer is omitted).

In an embodiment, the holes H1, H2, H3, H4, and H5 may overlap each other in the transmission area TA in a plan view. The holes H1, H2, H3, H4, and H5 may be formed at once in the same process after forming the insulating layers IL1, IL2, IL3 and IL4 and the pixel defining layer PDL, but the invention is not limited thereto. For example, the holes H1, H2, H3, H4, and H5 may each be formed through separate processes.

In an embodiment, the light emitting structures EMS may be disposed on the first pixel electrodes PE1. The light emitting structure EMS may include the light emitting layer EL, the first functional layer FL1, and the second functional layer FL2.

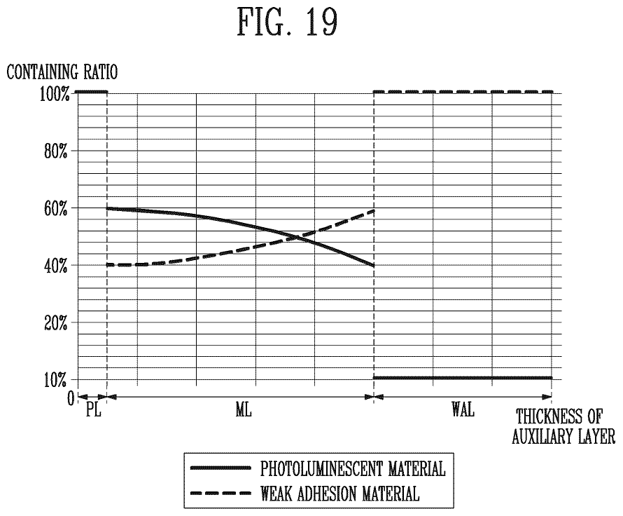

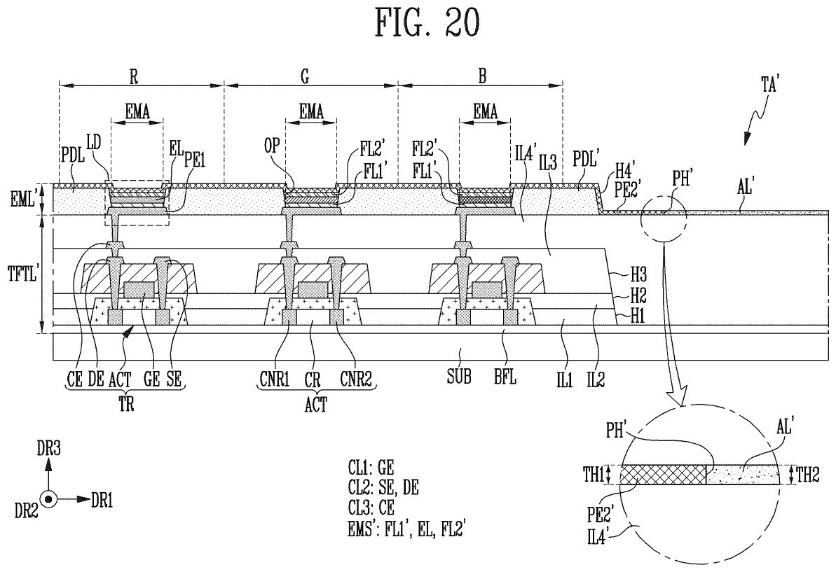

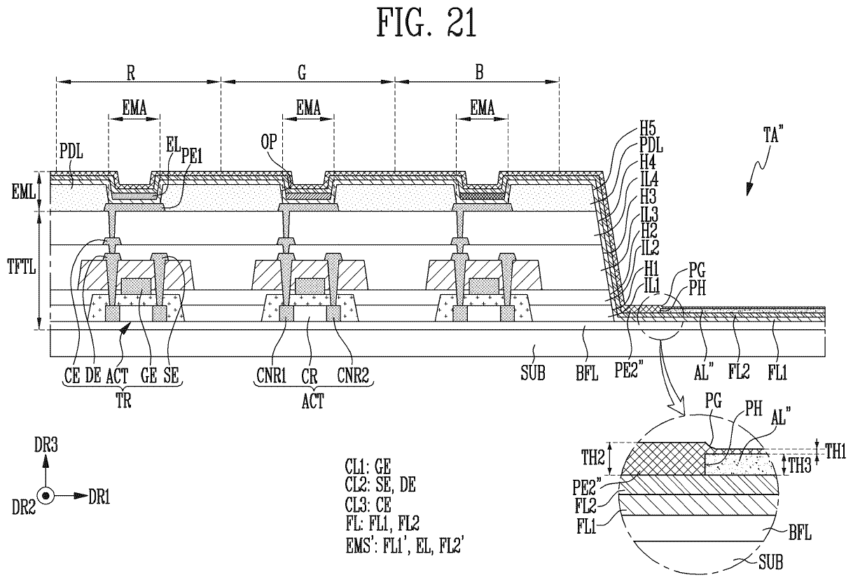

The light emitting structure EMS shown of FIG. 13 may fill the opening OP of the pixel defining layer PDL and may be entirely disposed on the pixel defining layer PDL. In other words, the light emitting structure EMS may extend throughout the sub-pixels R, G, and B. In this case, a portion of layers in the light emitting structure EMS may be disconnected or bent at boundaries between the sub-pixels R, G, and B. However, the invention is not limited thereto. For example, as will be described with reference to FIGS. 19 and 21 below, portions of the light emitting structure EMS corresponding to the sub-pixels R, G, and B may be separated from each other, and each of the portions may be disposed in the opening OP of the pixel defining layer PDL.

In an embodiment, the light emitting layer EL may include a high molecular material or a low molecular material and may generate light. For example, the light emitting layer EL may emit red, green, blue, or white light.

In an embodiment, the first functional layer FL1 may be disposed between the first pixel electrodes PE1 and the light emitting layer EL. The first functional layer FL1 may include an organic material and extend to the transmission area TA so as to overlap the transmission hole PH in a plan view. In an embodiment, the first functional layer FL1 may be disposed over the first pixel electrode PE1 and the pixel defining layer PDL. In addition, the first functional layer FL1 may cover side surfaces of the insulating layers IL1, IL2, IL3, and IL4, extend toward the transmission area TA, and cover a portion of the upper surface of the buffer layer BFL or the substrate SUB (when the buffer layer is omitted). For example, in the transmission area TA, the first functional layer FL1 may be disposed between the substrate SUB and the second functional layer FL2.

The first functional layer FL1 may be a single layer or multiple layers. For example, the first functional layer FL1 may be a hole transport layer HTL which is a single layer structure. In other embodiments, the first functional layer FL1 may include a hole injection layer HIL together with the hole transport layer HTL.

In an embodiment, the second functional layer FL2 may be disposed between the second pixel electrode PE2 and the light emitting layer EL. The second functional layer FL2 may include an organic material and extend to the transmission area TA so as to overlap the transmission hole PH in a plan view. In the transmission area TA, the second functional layer FL2 may be disposed on the first functional layer FL1.

The second functional layer FL2 may be a single layer or multiple layers. For example, the second functional layer FL2 may be an electron transport layer ETL which is a single layer structure. In other embodiments, the second functional layer FL2 may include an electron injection layer EIL together with an electron transport layer ETL.

In an embodiment, the second pixel electrode PE2 may be disposed on the light emitting structure EMS. and may extend over the sub-pixels R, G, and B. As described above, the second pixel electrode PE2 may be provided as a common electrode for the sub-pixels R, G, and B. In an embodiment, the second pixel electrode PE2 may include the transmission hole PH extending to the transmission area TA and overlapping the transmission area TA in a plan view.

In embodiments, the transmission hole PH may expose a portion of an upper surface of the second functional layer FL2. The area of the transmission hole PH may be smaller less than the area of the first to fifth holes H1, H2, H3, H4, and H5. For example, in FIG. 13, a width of the transmission hole PH is smaller than a width of the first hole H1 which has the smallest area among the holes H1, H2, H3, H4, and H5.

In an embodiment, in an upper light emitting structure emitting light in a direction facing the second pixel electrode PE2 based on the light emitting layer EL, the second pixel electrode PE2 may be formed of a transparent metal material such as ITO or IZO that may transmit light, or may be formed of a translucent metal material such as magnesium (Mg), silver (Ag), or an alloy of magnesium (Mg) and silver (Ag). As described above, when the second pixel electrode PE2 is formed of a translucent metal material, light output efficiency may be increased by a micro cavity.

In an embodiment, in a lower light emitting structure emitting light in a direction facing the first pixel electrode PE1 based on the light emitting layer EL, the second pixel electrode PE2 may be formed of a metal material of which a reflectance is high such as a stack structure of aluminum and titanium (Ti/Al/Ti), a stack structure of aluminum and ITO (ITO/Al/ITO), an APC alloy, and a stack structure of APC alloy and ITO (ITO/APC/ITO). The APC alloy is an alloy of silver (Ag), palladium (Pd), and copper (Cu).

In an embodiment, one of the first pixel electrodes PE1, a portion of the light emitting structure EMS overlapping it, and a portion of the second pixel electrode PE2 overlapping it may be understood as configuring one light emitting element LD. In other words, each of the light emitting elements LD of the sub-pixels R, G, and B may include one first pixel electrode PE1, a portion of the light emitting structure EMS overlapping it, and a portion of the second pixel electrode PE2 overlapping it. In each of the sub-pixels R, G, and B, holes injected from the first pixel electrode PE1 and electrons injected to the second pixel electrode PE2 may be transported into the light emitting layer EL of the light emitting structure EMS to form excitons, and light may be generated when the excitons are transited from an excited state to a ground state. A luminance of light may be determined according to an amount of a current flowing through the light emitting layer EL. According to a configuration of the light emitting layer EL, a wavelength range of the generated light may be determined.

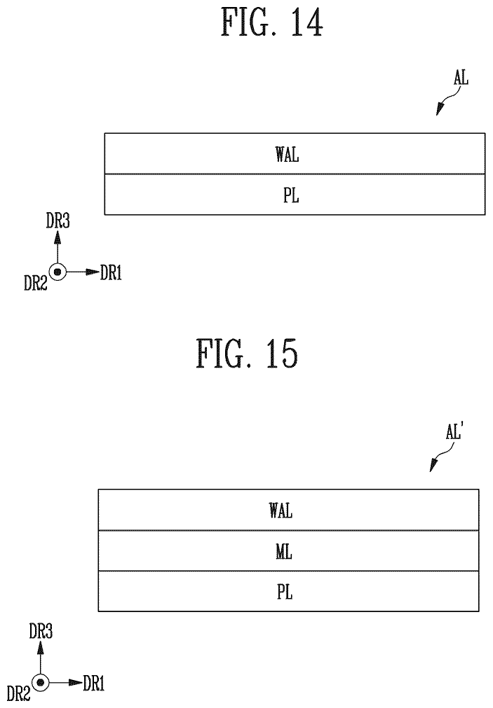

In an embodiment, the auxiliary layer AL may be received in the transmission hole PH positioned in the transmission area TA. The auxiliary layer AL may overlap the first functional layer FL1 and the second functional layer FL2 in the transmission area TA in a plan view, and may not overlap the second pixel electrode PE2. In other words, light incident from the outside into the transmission area TA may be transmitted without reflection or interference of the second pixel electrode PE2. A specific configuration of the auxiliary layer AL may be described in more detail with reference to FIGS. 14 to 18 below.

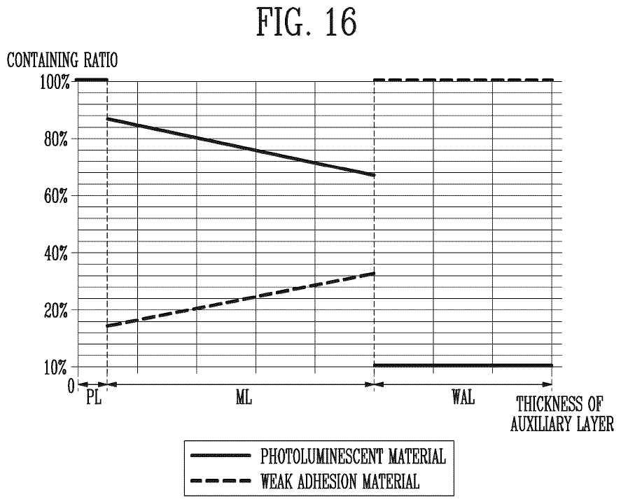

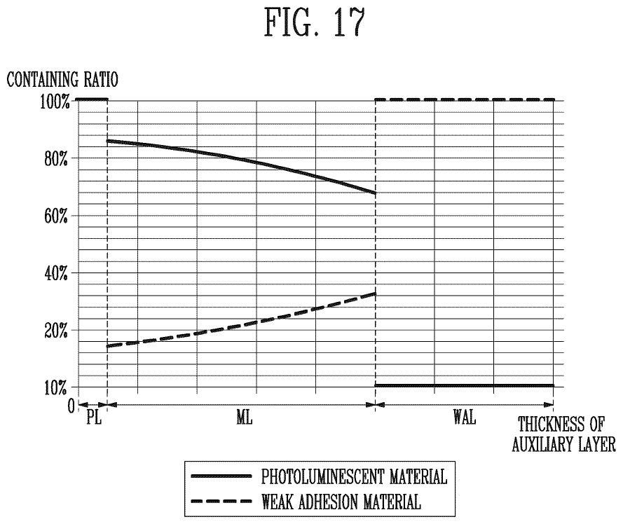

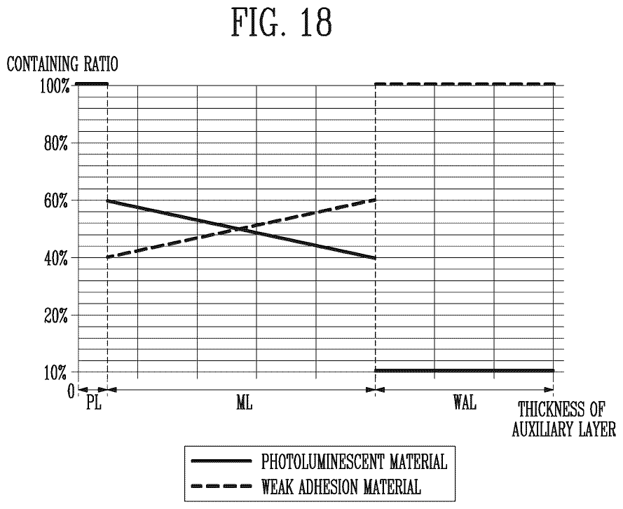

FIG. 14 is a schematic cross-sectional view illustrating a stack structure of an auxiliary layer, according to an embodiment. FIG. 15 is a schematic cross-sectional view illustrating a stack structure of an auxiliary layer, according to another embodiment. FIG. 16 is a graph illustrating a comparison of a containing ratio of the photoluminescent material and the weak adhesion material based on a thickness of the auxiliary layer shown of FIG. 15, according to an embodiment. FIG. 17 is a modified example of the graph shown of FIG. 16, according to an embodiment. FIG. 18 is another modified example of the graph shown of FIG. 16, according to an embodiment. FIG. 19 is another modified example of the graph shown of FIG. 17, according to an embodiment.

In an embodiment and referring to FIG. 14, the auxiliary layer AL may include a photoluminescent layer PL and a weak adhesion layer WAL.

The photoluminescent layer PL may be disposed on the second functional layer FL2 in the transmission area TA. In an embodiment, since both of the photoluminescent layer PL and the second functional layer FL2 are formed of an organic material, an interface adhesion may be further improved compared to a case where one of the photoluminescent layer PL and the second functional layer FL2 is an inorganic material.

The photoluminescent layer PL may absorb light of a specific wavelength and perform photoluminescence. In an embodiment, the photoluminescent layer PL may include an organic material that absorbs long-wave UV light of about 315 nm to about 400 nm and emits visible light. A photoluminescence characteristic of the photoluminescence layer PL may be used to align a mask to an intended position in a manufacturing process of the display device 10. For example, the photoluminescent layer PL may emit visible light by absorbing long-wave UV light of about 315 nm to about 400 nm and emit visible light in a process of depositing the weak adhesion layer WAL. As described above, the visible light emitted from the photoluminescent layer PL may be recognized by an industrial microscope (industry checking and measure microscope (ICM)) and used to position the mask at an accurate position, and as a result, yield of the display device 10 may be improved by depositing the weak adhesion layer WAL and the second pixel electrode PE2 at accurate positions, respectively.

The weak adhesion layer WAL may be disposed on the photoluminescent layer PL in the transmission area TA.

In an embodiment, the weak adhesion layer WAL may include a material of which an interface adhesive strength is weak when bonded to a metal material such as the second pixel electrode PE2. The interface adhesive strength of the weak adhesion layer WAL to the second pixel electrode PE2 may be lower than that of the photoluminescent layer PL. For example, the weak adhesion layer WAL may include Liq; [8-Quinolinolato Lithium], N,N-diphenyl-N,N-bis(9-phenyl-9H-carbazol-3-yl)biphenyl-4,4′-diamine; HT01, N(diphenyl-4-yl)9,9-dimethyl-N-(4 (9-phenyl-9H-carbazol-3-yl)phenyl)-9H-fluorene-2-amine; HT211, 2-(4-(9,10-di(naphthalene-2-yl)anthracene-2-yl)phenyl)-1-phenyl-1H-benzo-[D]imidazole; LG201, or the like.

Due to the characteristic of the weak adhesion layer WAL described above, the second pixel electrode PE2 may not be formed on an upper surface of the weak adhesion layer WAL in a deposition process of the second pixel electrode PE2. As described above, since the second pixel electrode PE2 does not exist in the transmission area TA overlapping the weak adhesion layer WAL in a plan view, light incident from the outside into the transmission area TA may not be reflected or interfered by the second pixel electrode PE2. As a result, the transmittance of the transmission area TA may be improved.

Referring to FIG. 15, an auxiliary layer AL′ may further include a mixed layer ML, according to an embodiment.

In an embodiment, the mixed layer ML may be disposed between the photoluminescent layer PL and the weak adhesion layer WAL and may include a material in which a photoluminescent material forming the photoluminescent layer PL and a weak adhesion material forming the weak adhesion layer WAL are mixed. In embodiments, the containing ratio of each of the photoluminescent material and the weak adhesion material in the mixed layer ML may vary. For example, the mixed layer ML may be a heterogeneous mixture.

In an embodiment and referring to FIG. 16, the containing ratio of the photoluminescent material contained in the mixed layer ML may decrease along a direction from the photoluminescent layer PL to the weak adhesion layer WAL (hereinafter referred to as a “thickness direction of the auxiliary layer AL”), and the containing ratio of the weak adhesion material contained in the mixed layer ML may increase along the thickness direction of the auxiliary layer AL. In embodiments, the containing ratio of the photoluminescent material in the mixed layer ML may be greater than the containing ratio of the weak adhesion material, regardless of a point based on the thickness direction of the auxiliary layer AL. This is designed from a point of view that there is no need to increase the containing ratio of the weak adhesion layer WAL when an expected effect of the weak adhesion layer WAL preventing formation of the second pixel electrode PE2 is sufficient regardless of the containing ratio of the weak adhesion layer WAL. Accordingly, it may be understood that the containing ratio of the photoluminescent material in the mixed layer ML may be relatively increased to maximize a photoluminescent effect of the photoluminescent layer PL.

For example, in an embodiment, the containing ratio of the photoluminescent material in the mixed layer ML may decrease from about 80% or more to about 70%, and the containing ratio of the weak adhesion material may increase from about 20% or less to about 30%. However, the containing ratio of the photoluminescent material and the weak adhesion material in the mixed layer ML shown of FIG. 16 may be an example, and an expression “containing ratio is high” is not limited to about 60% as shown in the graph and may be understood to mean an containing ratio exceeding 50%.

FIG. 16 illustrates an embodiment where the photoluminescent material linearly decreases and the weak adhesion material also linearly increases in the mixed layer ML, but is not limited thereto. In another embodiment and referring to FIG. 17, the photoluminescent material may parabolically decrease and the weak adhesion material may parabolically increase in the mixed layer ML.

In still another embodiment and referring to FIG. 18, a portion of the mixed layer ML adjacent to the photoluminescent layer PL may contain more photoluminescent material than the weak adhesion material, and another portion of the mixed layer ML disposed adjacent to the weak adhesion layer WAL may contain more weak adhesion materials than the photoluminescent material. In other words, in a lower portion of the mixed layer ML, the containing ratio of the photoluminescent material may be high, and in an upper portion of the mixed layer ML, the containing ratio of the weak adhesion material may be high. In this embodiment, a characteristic of the photoluminescent layer PL that absorbs light of a specific wavelength and emits light may be strengthened, and a characteristic of the weak adhesion layer WAL of which the interface adhesive strength is weak to the second pixel electrode PE2 may also be strengthened. Through this, the mask may be accurately aligned to the intended position in a formation process of the weak adhesion layer WAL and the second pixel electrode PE2, and the second pixel electrode PE2 may not be formed on the weak adhesion layer WAL. As described above, structures that strengthen the characteristics of each of the photoluminescent layer PL and the weak adhesion layer WAL by configuring different ratios of the photoluminescent layer PL and the weak adhesion layer WAL of the upper and lower portions of the mixed layer ML are not mutually exclusive and may coexist with each other. As a result, yield improvement and transmittance improvement of the transmission area TA may be strengthened together.

For example, in an embodiment, the containing ratio of the photoluminescent material may decrease from about 60% to about 40% and the containing ratio of the weak adhesion material may increase from about 40% to about 60% in the mixed layer ML. FIG. 18 illustrates a graph in which the containing ratio of the photoluminescent material linearly decreases and the containing ratio of the weak adhesion material linearly increases, but is not limited thereto. For example, as shown of FIG. 19, the photoluminescent material may parabolically decrease from about 60% to about 40% and the weak adhesion material may parabolically increase from about 40% to about 60% in the mixed layer ML.

However, the containing ratio of the photoluminescent material and the weak adhesion material in the mixed layer ML shown in FIGS. 18 and 19 is also an example, and an expression “containing ratio is high” is limited to a specific value as described above with reference to FIG. 16 and may be understood to mean a containing ratio exceeding about 50%.

Hereinafter, with reference to FIGS. 20 to 22, other embodiments of the first area A1 described with reference to FIG. 13 are described in more detail.

FIG. 20 illustrates another embodiment of the thin film transistor layer and the light emitting element layer shown of FIG. 13.

In an embodiment and referring to FIG. 20, the thin film transistor layer TFTL′ may include a buffer layer BFL, a semiconductor layer ACT, a first insulating layer IL1, a first conductive layer CL1, a second insulating layer IL2, a second conductive layer CL2, a third insulating layer IL3, a third conductive layer CL3, and a fourth insulating layer IL4′. The buffer layer BFL, the semiconductor layer ACT, the first insulating layer IL1, the first conductive layer CL1, the second insulating layer IL2, the second conductive layer CL2, the third insulating layer IL3, and the third conductive layer CL3 shown in FIG. 20 may be provided similarly to the buffer layer BFL, the semiconductor layer ACT, the first insulating layer IL1, the first conductive layer CL1, the second insulating layer IL2, the second conductive layer CL2, the third insulating layer IL3, and the third conductive layer CL3. Accordingly, an overlapping description is omitted below.

In an embodiment, the fourth insulating layer IL4′ may be disposed on the third insulating layer IL3. In addition, the fourth insulating layer IL4′ may be disposed under the first pixel electrodes PEL and may cover remaining insulating layers, that is, the insulating layers IL1, IL2, and IL3. For example, the fourth insulating layer IL4′ may be disposed between the third insulating layer IL3 and the first pixel electrodes PE1. The fourth insulating layer IL4′ may extend to a transmission area TA′ so as to overlap a transmission hole PH′ in a plan view, and may cover a portion of an upper surface of the buffer layer BFL or the substrate SUB exposed by the holes H1, H2, and H3.

In an embodiment, the fourth insulating layer IL4′ may be a via layer. The fourth insulating layer IL4′ may serve to buffer so that the fourth insulating layer IL4′ covers lower components such as the insulating layers IL1, IL2, IL3, and IL4′ and the thin film transistors TR disposed in each pixel SP to protect lower layers thereof from external shock, or may include various materials suitable for protecting the lower layers thereof from oxygen and a foreign substance such as dust or moisture. In addition, the fourth insulating layer IL4 may offset a step caused by the holes H1, H2, and H3. Accordingly, the fourth insulating layer IL4′ may provide a flat surface on which light emitting elements LD, the pixel defining layer PDL′, and the auxiliary layer AL′ are disposed.

In an embodiment, the fourth insulating layer IL4′ may include the same material as the third insulating layer IL3, or may include a material selected from among materials exemplified as a configuration material of the fourth insulating layer IL4′.

In an embodiment, a light emitting element layer EML′ may be disposed on the thin film transistor layer TFTL′.

The light emitting element layer EML′ may include first pixel electrodes PE1, the pixel defining layer PDL′, light emitting structures EMS′, a second pixel electrode PE2′, and the auxiliary layer AL′.

The first pixel electrodes PE1, the pixel defining layer PDL′, the second pixel electrode PE2′, and the auxiliary layer AL′ shown in FIG. 20 may be configured similarly to the first pixel electrodes PE1, the pixel defining layer PDL, the second pixel electrode PE2, and the auxiliary layer AL shown of FIG. 13, except that the first pixel electrodes PE1, the pixel defining layer PDL′, a portion of the second pixel electrode PE2′ positioned in the transmission area TA′, and the auxiliary layer AL′ are disposed on the fourth insulating layer IL4′. Therefore, an overlapping description is omitted below.

In an embodiment, the light emitting structure EMS′ may include a first functional layer FL1′, the light emitting layer EL, and a second functional layer FL2′. The light emitting structures EMS′ corresponding to the sub-pixels R, G, and B may be disposed on the first pixel electrodes PE1 and may be separated from each other, and each of the light emitting structures EMS′ may be disposed in an opening OP of the pixel defining layer PDL′.

In an embodiment, the light emitting layer EL, the first functional layer FL1′, and the second functional layer FL2′ shown in FIG. 20 may be configured similarly to the light emitting layer EL, the first functional layer FL1, and the second functional layer FL2 described with reference to FIG. 13 except for a disposition relationship of the first functional layer FL1′ and the second functional layer FL2′ to be described later. Accordingly, an overlapping description is omitted below.

In an embodiment, the first functional layer FL1′ and the second functional layer FL2′ may be disposed in each of the openings OP defined by the pixel defining layer PDL′ similarly to the light emitting layer EL. The first functional layer FL1′ may include an organic material and may be disposed between the first pixel electrodes PE1 and the light emitting layer EL. The second functional layer FL2′ may include an organic material and may be disposed between the light emitting layer EL and the second pixel electrode PE2′. In addition, the first functional layer FL1′ and the second functional layer FL2′ may not extend to the transmission area TA′ and may be disposed in the emission area EMA defined by the pixel defining layer PDL′.

In an embodiment, the second pixel electrode PE2′ may be disposed on the light emitting structure EMS′ and may extend throughout the sub-pixels R, G, and B. As described above, the second pixel electrode PE2′ may be provided as a common electrode for the sub-pixels R, G, and B. In an embodiment, the second pixel electrode PE2′ may include the transmission hole PH′ that extends to the transmission area TA′ and that overlaps the transmission area TA′ in a plan view.

In an embodiment, the transmission hole PH′ may expose a portion of an upper surface of the fourth insulating layer IL4′, where the area of the transmission hole PH′ may be less than the area of the first to fourth holes H1, H2, H3, and H4′. For example, in FIG. 20, a width of the transmission hole PH′ is shown to be smaller than a width of the first hole H1, which has the smallest area among the holes H1, H2, H3, and H4′.

According to this embodiment, the auxiliary layer AL′ may be received in the transmission hole PH′ to be positioned in the transmission area TA′, and may be disposed on the fourth insulating layer IL4′ to be positioned in the transmission area TA′. For example, the auxiliary layer AL′ may overlap the fourth insulating layer IL4′ in the transmission area TA′ in a plan view, and may not overlap the second pixel electrode PE2′. In other words, light incident from the outside to the transmission area TA′ may be transmitted without reflection or interference by the second pixel electrode PE2′.

The auxiliary layer AL′ shown of FIG. 20 may be provided similarly to the auxiliary layer AL described with reference to FIGS. 14 to 19. Therefore, an overlapping description is omitted below.

FIG. 21 illustrates another embodiment of the second pixel electrode shown of FIG. 13.

In an embodiment and referring to FIG. 21, except for a second pixel electrode PE2″ and an auxiliary layer AL″ to be described later, remaining components are the same as respective components described with reference to FIG. 13, and thus an overlapping description is omitted below.

In an embodiment, the second pixel electrode PE2″ shown in FIG. 21 may be disposed on the second functional layer FL2 and may extend further to a transmission area TA″ to overlap the transmission area TA″ in a plan view. The second pixel electrode PE2″ may include a transmission groove PG in the transmission area TA″, where the transmission groove PG may be understood as one of a concave portion, a recess, and a groove.

In an embodiment, the auxiliary layer AL″ may be disposed under the second pixel electrode PE2″ in the transmission area TA″, and may overlap the transmission groove PG in a plan view. Specifically, the photoluminescent layer (refer to PL of FIG. 14 or 15) of the auxiliary layer AL″ may be disposed on the second functional layer FL2, and the weak adhesion layer (refer to WAL of FIG. 14 or 15) of the auxiliary layer AL″ may be disposed under the second pixel electrode PE2″.

In an embodiment, a portion of the second pixel electrode PE2″ that overlaps the auxiliary layer AL″ may have a first thickness TH1, and another portion of the second pixel electrode PE2″ that does not overlap the auxiliary layer AL″ may have a second thickness TH2. In addition, the auxiliary layer AL″ may have a third thickness TH3. In this case, the first thickness TH1 may be thinner than the second thickness TH2. In addition, in an embodiment, a thickness obtained by adding the first thickness TH1 and the third thickness TH3 may be thinner than the second thickness TH2. As described above, this is due to the nature of the weak adhesion layer WAL including a material with a low interface adhesive strength to a metal material. The first thickness TH1 of the second pixel electrode PE2″ corresponding to a portion that overlaps the weak adhesion layer WAL may be formed to be very thin compared to the second thickness TH2 of the second pixel electrode PE2″ corresponding to a portion that does not overlap the weak adhesion layer WAL.

As described above, since the second pixel electrode PE2″ having the first thickness TH1 which may be very thin compared to another area is disposed in the transmission area TA″ overlapping the weak adhesion layer WAL in a plan view, a phenomenon in which light incident from the outside to the transmission area TA″ is reflected or interfered by the second pixel electrode PE2″ may be significantly reduced. As a result, a transmittance of the transmission area TA″ may be improved.

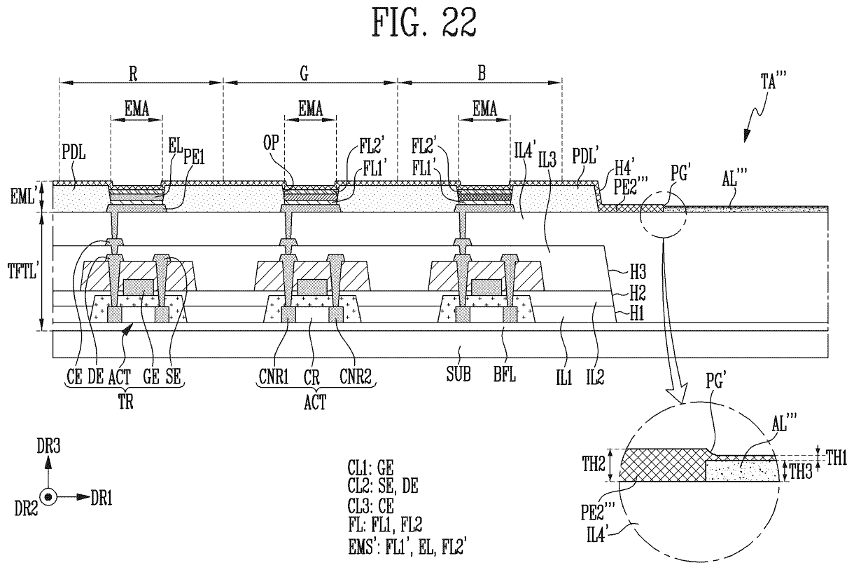

FIG. 22 illustrates another embodiment of the second pixel electrode shown of FIG. 20.

In an embodiment and referring to FIG. 22, except for a second pixel electrode PE2″′ and an auxiliary layer AL″′ to be described later, remaining components are the same as respective components described with reference to FIG. 20, and thus an overlapping description is omitted below.

In an embodiment, the second pixel electrode PE2″′ shown of FIG. 22 may be disposed on the fourth insulating layer IL4′ and may include a transmission groove PG′ extending to a transmission area TA″′ and overlapping the transmission area TA″′ in a plan view. The transmission groove PG′ may be understood as one of a concave portion, a recess, and a groove.

The auxiliary layer AL″′ may be disposed between the fourth insulating layer IL4′ and the second pixel electrode PE2″′ in the transmission area TA″′ and may overlap the transmission groove PG′ in a plan view. Specifically, the photoluminescent layer (refer to PL of FIG. 14 or 15) of the auxiliary layer AL″′ may be disposed on the fourth insulating layer IL4′, and the weak adhesion layer (refer to WAL of FIG. 14 or 15) of the auxiliary layer AL″′ may be disposed under the second pixel electrode PE2″.

In an embodiment, a portion of the second pixel electrode PE2′″ that overlaps the auxiliary layer AL′″ may have a first thickness TH1, and another portion of the second pixel electrode PE2″′ that does not overlap the auxiliary layer AL″′ may have a second thickness TH2. In addition, the auxiliary layer AL′″ may have a third thickness TH3. In this case, the first thickness TH1 may be thinner than the second thickness TH2. In addition, in an embodiment, a thickness obtained by adding the first thickness TH1 and the third thickness TH3 may be thinner than the second thickness TH2. As described above, this is due to the nature of the weak adhesion layer WAL including a material with a low interface adhesive strength to a metal material. The first thickness TH1 of the second pixel electrode PE2″′ corresponding to a portion that overlaps the weak adhesion layer WAL may be formed to be very thin compared to the second thickness TH2 of the second pixel electrode PE2′″ corresponding to a portion that does not overlap the weak adhesion layer WAL.

As described above, since the second pixel electrode PE2″ having the first thickness TH1 is very thin compared to another area is disposed in the transmission area TA″′ overlapping the weak adhesion layer WAL in a plan view, a phenomenon in which light incident from the outside to the transmission area TA″′ is reflected or interfered by the second pixel electrode PE2′″ may be significantly reduced. As a result, a transmittance of the transmission area TA″′ may be improved.

Example embodiments have been disclosed herein, and although specific terms are employed, they are used and are to be interpreted in a generic and descriptive sense only and not for purpose of limitation. In some instances, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the invention.

What is claimed is:

1. A display device including a transmission area disposed in a display area and transmitting light provided from an outside, the display device comprising:
a substrate;
a thin film transistor layer disposed on the substrate and including a plurality of thin film transistors; and
a light emitting element layer disposed on the thin film transistor layer,
wherein the light emitting element layer comprises:
a plurality of first pixel electrodes electrically connected to the plurality of thin film transistors;
a light emitting structure disposed on the plurality of first pixel electrodes;
a second pixel electrode disposed on the light emitting structure and including a transmission hole overlapping the transmission area; and
an auxiliary layer disposed in the transmission hole, wherein
the auxiliary layer comprises:
a photoluminescent layer absorbing light of a specific wavelength and performing photoluminescence; and
a weak adhesion layer disposed on the photoluminescent layer.

2. The display device according to claim 1, wherein the photoluminescent layer includes an organic material absorbing long-wave UV light of about 315 nm to about 400 nm and emitting visible light.

3. The display device according to claim 1, wherein the weak adhesion layer includes a material having an interface adhesive strength to the second pixel electrode that is lower than an interface adhesive strength of a material of the photoluminescent layer.

4. The display device according to claim 1, wherein the auxiliary layer further includes a mixed layer disposed between the photoluminescent layer and the weak adhesion layer, wherein
the mixed layer includes a material in which a photoluminescent material forming the photoluminescent layer and a weak adhesion material forming the weak adhesion layer are mixed.

5. The display device according to claim 4, wherein a containing ratio of the photoluminescent material contained in the mixed layer is greater than a containing ratio of the weak adhesion material.

6. The display device according to claim 4, wherein a portion of the mixed layer disposed adjacent to the photoluminescent layer contains more of the photoluminescent material than the weak adhesion material, and
wherein another portion of the mixed layer disposed adjacent to the weak adhesion layer contains more of the weak adhesion material than the photoluminescent material.

7. The display device according to claim 4, wherein a containing ratio of the photoluminescent material contained in the mixed layer decreases along a direction from the photoluminescent layer to the weak adhesion layer, and
wherein a containing ratio of the weak adhesion material contained in the mixed layer increases along the direction from the photoluminescent layer to the weak adhesion layer.

8. The display device according to claim 4, wherein a containing ratio of the photoluminescent material contained in the mixed layer decreases linearly along a direction from the photoluminescent layer to the weak adhesion layer, and
wherein a containing ratio of the weak adhesion material contained in the mixed layer increases linearly along the direction from the photoluminescent layer to the weak adhesion layer.

9. The display device according to claim 4, wherein a containing ratio of the photoluminescent material contained in the mixed layer decreases parabolically along a direction from the photoluminescent layer to the weak adhesion layer, and
wherein a containing ratio of the weak adhesion material contained in the mixed layer increases parabolically along the direction from the photoluminescent layer to the weak adhesion layer.

10. The display device according to claim 1, wherein the light emitting structure comprises:
a light emitting layer generating light;
a first functional layer disposed between the first pixel electrodes and the light emitting layer; and
a second functional layer disposed between the second pixel electrode and the light emitting layer.

11. The display device according to claim 10, wherein the first functional layer includes an organic material and extends to the transmission area to overlap the transmission hole in a plan view,
the second functional layer includes an organic material and extends to the transmission area to overlap the transmission hole in a plan view,
wherein the second functional layer is disposed on the first functional layer in the transmission area, and
the photoluminescent layer is disposed on the second functional layer in the transmission area.

12. The display device according to claim 1, wherein the thin film transistor layer further includes a plurality of insulating layers,
wherein one insulating layer of the plurality of insulating layers is disposed under the first pixel electrodes and covers other insulating layers of the plurality of insulating layers except for the one insulating layer, wherein
the one insulating layer extends to the transmission area so as to overlap the transmission hole, and
the auxiliary layer is disposed on the one insulating layer in the transmission hole.

13. The display device according to claim 12, wherein the other insulating layers include holes overlapping the transparent hole.

14. A display device including a transmission area disposed in a display area and transmitting light provided from an outside source, the display device comprising:
a substrate;
a thin film transistor layer disposed on the substrate and including a plurality of thin film transistors; and
a light emitting element layer disposed on the thin film transistor layer,
wherein the light emitting element layer comprises:
a plurality of first pixel electrodes electrically connected to the plurality of thin film transistors;
a light emitting structure disposed on the first pixel electrodes;
a second pixel electrode disposed on the light emitting structure and including a transmission groove overlapping the transmission area; and
an auxiliary layer disposed under the second pixel electrode and overlapping the transmission groove, wherein
the auxiliary layer comprises:
a photoluminescent layer absorbing light of a specific wavelength and performing photoluminescence; and
a weak adhesion layer disposed on the photoluminescent layer.

15. The display device according to claim 14, wherein a portion of the second pixel electrode overlapping the auxiliary layer has a first thickness, and
another portion of the second pixel electrode that does not overlap the auxiliary layer has a second thickness, wherein
the first thickness is thinner than the second thickness.

16. The display device according to claim 14, wherein the photoluminescent layer includes an organic material absorbing long-wave UV light of about 315 nm to about 400 nm and emitting visible light.

17. The display device according to claim 14, wherein the weak adhesion layer includes a material having an interface adhesive strength to the second pixel electrode that is lower than an interface adhesive strength to a material of the photoluminescent layer.

18. The display device according to claim 14, wherein the auxiliary layer further comprises:
a photoluminescent material forming the photoluminescent layer; and
a mixed layer formed of a material in which a weak adhesion material forming the weak adhesion layer is mixed, wherein
the mixed layer is disposed between the photoluminescent layer and the weak adhesion layer.

19. The display device according to claim 14, wherein the light emitting structure comprises:
a light emitting layer generating light;
a first functional layer disposed between the first pixel electrodes and the light emitting layer;
a second functional layer disposed between the second pixel electrode and the light emitting layer, wherein
the first functional layer includes an organic material and extends to the transmission area to overlap the transmission groove in a plan view,
the second functional layer includes an organic material and extends to the transmission area to overlap the transmission groove in a plan view, and
the photoluminescent layer is disposed on the second functional layer in the transmission area.

20. The display device according to claim 14, wherein the thin film transistor layer further includes a plurality of insulating layers, wherein
one insulating layer of the plurality of insulating layers is disposed under the first pixel electrodes and covers other insulating layers of the plurality of insulating layers except for the one insulating layer, wherein
the one insulating layer extends to the transmission area so as to overlap the transmission groove, and
the photoluminescent layer is disposed on the one insulating layer in the transmission area.
